(19) United States
(12) Patent Application Publication
(10) Pub. No.: US 2018/0320263 A1
(43) Pub. Date: Nov. 8, 2018

(54) Methods, Systems, and Apparatus for Fabricating a Physical Vapor Deposition Manrel-Target Assembly

(71) Applicant: Advanced Design Innovations, Inc., Mesa, AZ (US)

(72) Inventor: Gerald L. Martinez, Mesa, AZ (US)

(21) Appl. No.: 15/587,277

(22) Filed: May 4, 2017

(51) Int. Cl. C23C 14/34

(52) U.S. Cl. CPC C23C 14/3407

(57) ABSTRACT

Methods, systems, and apparatus for fabricating a physical vapor deposition (PVD) mandrel-target assembly are provided. One method includes providing a mandrel and a PVD target and placing a hollow center portion of the PVD target around a portion of the mandrel such that the portion of the mandrel resides in the hollow portion to create a PVD mandrel-target assembly including space between an exterior surface of the mandrel and an interior surface of the PVD target. The method further includes heating an interior surface of the mandrel, an exterior surface of the PVD target, and an adhesive material to a predetermined temperature and filling the space with the adhesive material to connect the exterior surface of the mandrel and the interior surface of the PVD target. Systems and apparatus for performing the above method are also provided.

### BACKGROUND

### Field of the Technology

The present technology relates generally to physical vapor deposition (PVD), and more particularly to, methods, systems, and apparatus for fabricating a mandrel-target assembly utilized in a PVD process.

### Description of Related Art

Cathodic sputtering is widely used for depositing a thin layer or film of material from a physical vapor deposition (PVD) mandrel-target assembly comprised of a mandrel and a PVD target onto a substrate (e.g., glass). Glass substrates with a deposited thin layer or film are used in many technologies including, for example, architectural glass, displays, touch panels, and solar cells, among other uses.

To deposit a thin layer or film on a substrate, a PVD mandrel-target assembly is placed together with an anode in a chamber filled with an inert gas, preferably argon (Ar). The substrate is positioned in the chamber near the anode with a receiving surface oriented normal to a path between the PVD mandrel-target assembly and the anode. A high voltage electric field is applied across the PVD mandrel-target assembly and the anode causing electrons to eject from the PVD mandrel-target assembly and ionize the inert gas. The positively charged ions of the inert gas are then propelled against a sputtering surface of the PVD target due to the electric field. The ion bombardment against the sputtering surface of the PVD target causes portions of the material of the sputtering surface to dislodge from the sputtering surface and deposit as a thin film or layer on the receiving surface of the substrate at an opposite end of the chamber.

Previous techniques to fabricate mandrel-target assemblies for a PVD process were performed manually. That is, previous techniques used one or more humans to manually combine a mandrel with one or more PVD targets to create a PVD mandrel-target assembly. Using manual labor not only makes the previous fabrication techniques less efficient than they otherwise could be with respect to time and/or cost, using humans also severely limits and/or handicaps the manner, reliability, accuracy, and/or quality in which a mandrel is combined with one or more PVD target(s) in fabricating a PVD mandrel-target assembly.

### SUMMARY

The present disclosure describes methods, systems, and apparatus for fabricating a physical vapor deposition (PVD) mandrel-target assembly. One method includes providing a mandrel comprising a first exterior surface, a first interior surface defining a first hollow center portion of the mandrel, and a first pair of lateral dimensions, providing a PVD target comprising a second exterior surface, a second interior surface defining a second hollow center portion of the PVD target, and a second pair of lateral dimensions greater than the first pair of lateral dimensions, and placing the second hollow center portion of the PVD target around a first portion of the mandrel such that the first portion resides in the second hollow portion to create a PVD mandrel-target assembly including space between the first exterior surface of the mandrel and the second interior surface of the PVD target. The method further includes heating the second exterior surface of the PVD target to a predetermined temperature, heating the first interior surface of the mandrel to the predetermined temperature, heating an adhesive material to the predetermined temperature, and filling the space with the heated adhesive material to couple the first exterior surface of the mandrel and the second interior surface of the PVD target such that the heated adhesive material, the first exterior surface of the mandrel, and the second interior surface of the PVD target include the predetermined temperature while the space is being filled.

A system includes means for providing mandrels and PVD targets in which each mandrel comprises a first exterior surface, a first interior surface defining a first hollow center portion of the mandrel, and a first pair of lateral dimensions and each PVD target comprises a second exterior surface, a second interior surface defining a second hollow center portion of the PVD target, and a second pair of lateral dimensions greater than the first pair of lateral dimensions, and means for placing the second hollow center portion of a PVD target around a portion of a mandrel such that the portion of the mandrel resides in the second hollow center portion to create a PVD mandrel-target assembly including space between the first exterior surface of the mandrel and the second interior surface of the PVD target. The system further includes an internal heater removably in thermal communication with the first interior surface of the mandrel and configured to heat the first interior surface to a predetermined temperature, an external heater removably in thermal communication with the second exterior surface of the PVD target and configured to heat the second exterior surface to the predetermined temperature, and a boiler removably in fluid communication with the space, the boiler configured to heat an adhesive material to the predetermined temperature and fill the space with the heated adhesive material such that the boiler, the external heater, and the internal heater are cooperatively configured to heat the adhesive material, the first interior surface of the mandrel, and the second exterior surface of the PVD target to the predetermined temperature while the space is being filled.

One apparatus includes a source module that operates an articulator and conveyor system that provides a predetermined pattern of mandrels and PVD targets to a robotic load/unload assembly in which each mandrel comprises a first exterior surface, a first interior surface defining a first hollow center portion of the mandrel, and a first pair of lateral dimensions and each PVD target comprises a second exterior surface, a second interior surface defining a second hollow center portion of the PVD target, and a second pair of lateral dimensions greater than the first pair of lateral dimensions, and an assembly module that operates the robotic load/unload assembly to place a second hollow center portion of a PVD target around a portion of a mandrel such that the portion of the mandrel resides in the second hollow center portion to create a PVD mandrel-target assembly including space between the first exterior surface of the mandrel and the second interior surface of the PVD target. The apparatus further includes an internal heater module that operates an internal heater removably in thermal communication with the first interior surface of the mandrel and configured to heat the first interior surface to a predetermined temperature, an external heater module that operates an external heater removably in thermal communication with the second exterior surface of the PVD target and configured to heat the second exterior surface to the predetermined temperature, and a boiler module that operates a boiler removably in fluid communication with the space and configured to heat an adhesive material to the predetermined temperature and fill the space with the heated adhesive material such that the boiler module, the external heater module, and the internal heater module are cooperatively configured to heat the adhesive material, the first interior surface of the mandrel, and the second exterior surface of the PVD target to the predetermined temperature while the space is being filled.

The technology disclosed herein provides a number of advantages and benefits over prior solutions, including, but not limited to, being more efficient, reliable, and/or accurate and/or including better/higher quality than other techniques, such as those described in the Background. It should be understood that the foregoing advantages and benefits are provided by way of example and that the technology disclosed herein may have numerous further advantages and benefits. Further, it should be understood that the Summary describes various example aspects of the subject matter of this disclosure and is not intended to encompass every inventive aspect.

### BRIEF DESCRIPTION OF THE DRAWINGS

To readily understand the advantages and benefits of the technology, a more particular description of the technology briefly described above will be rendered by reference to specific embodiments that are illustrated in the appended drawings. Understanding that these drawings depict typical embodiments of the technology, and are therefore not to be considered to be limiting of its scope, the technology will be described and explained with additional specificity and detail through the use of the accompanying drawings, in which:

FIG. 1 is a diagram of one embodiment of a mandrel;

FIG. 2 is a diagram of one embodiment of a physical vapor deposition (PVD) target;

FIG. 3 is a diagram of a PVD mandrel-target assembly including the mandrel of FIG. 1 and the PVD target of FIG. 2;

FIG. 4 is a block diagram of one embodiment of a system for creating a PVD mandrel-target assembly;

FIG. 5A is a diagram of one embodiment of robotic load/unload assembly included in the system of FIG. 4;

FIG. 5B is a diagram of one embodiment of a hinge-grasp system included in the robotic load/unload assembly of FIG. 5A;

FIG. 6 is a diagram of one embodiment of an internal heater included in the system of FIG. 4;

FIG. 7 is a diagram of one embodiment of an external heater included in the system of FIG. 4;

FIG. 8 is a diagram of one embodiment of a boiler included in the system of FIG. 4;

FIG. 9A is a block diagram of one embodiment of an operator controller included in the system of FIG. 4;

FIG. 9B is a block diagram of another embodiment of an operator controller included in the system of FIG. 4;

FIG. 10 is a flow diagram of one embodiment of a method for creating the PVD mandrel-target assembly of FIG. 3; and

FIG. 11 is a flow diagram of another embodiment of a method for creating the PVD mandrel-target assembly of FIG. 3.

### DETAILED DESCRIPTION OF THE DRAWINGS

The innovative technology disclosed herein includes various aspects, such as methods, systems, apparatus, computer-readable media, computer program products, computing systems, etc., for fabricating a physical vapor deposition (PVD) mandrel-target assembly. It should be understood that the language used in the present disclosure has been principally selected for readability and instructional purposes, and not to limit the scope of the subject matter disclosed herein in any manner.

The technology disclosed herein provides a number of advantages and benefits over prior solutions, including, but not limited to, being more efficient, reliable, and/or accurate and/or including better/higher quality than other techniques, such as those described in the Background. It should be understood that the advantages and benefits discussed herein are provided by way of example and the technology disclosed herein may have numerous further advantages and benefits. Further, it should be understood that the Summary describes various example aspects of the subject matter of this disclosure and is not intended to encompass every inventive aspect.

Reference throughout this specification to “one embodiment,” “an embodiment,” or similar language means that a particular feature, structure, or characteristic described in connection with the embodiment is included in at least one embodiment. Thus, appearances of the phrases “in one embodiment,” “in an embodiment,” and similar language throughout this specification may, but do not necessarily, all refer to the same embodiment, but mean “one or more but not all embodiments” unless expressly specified otherwise. The terms “including,” “comprising,” “having,” and variations thereof mean “including but not limited to” unless expressly specified otherwise. An enumerated listing of items does not imply that any or all of the items are mutually exclusive and/or mutually inclusive, unless expressly specified otherwise. The terms “a,” “an,” and “the” also refer to “one or more” unless expressly specified otherwise.

Furthermore, the described features, advantages, and characteristics of the embodiments may be combined in any suitable manner. One skilled in the relevant art will recognize that the embodiments may be practiced without one or more of the specific features or advantages of a particular embodiment. In other instances, additional features and advantages may be recognized in certain embodiments that may not be present in all embodiments.

The present technology may include a system, a method, and/or a computer program product. The computer program product may include a computer-readable storage medium (or media) having computer-readable program instructions thereon for causing a processor to carry out aspects of the present technology.

The computer-readable storage medium can be a tangible device that can retain and store instructions for use by an instruction execution device. The computer-readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer-readable storage medium includes the following: a portable computer diskette, a hard disk, a random access memory (“RAM”), a read-only memory (“ROM”), an erasable programmable read-only memory (“EPROM” or Flash memory), a static random access memory (“SRAM”), a portable compact disc read-only memory (“CD-ROM”), a digital versatile disk (“DVD”), a memory stick, a floppy disk, a mechanically encoded device such as punch-cards or raised structures in a groove having instructions recorded thereon, and any suitable combination of the foregoing. A computer-readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer-readable program instructions described herein can be downloaded to respective computing/processing devices from a computer-readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer-readable program instructions from the network and forwards the computer-readable program instructions for storage in a computer-readable storage medium within the respective computing/processing device.

Computer-readable program instructions for carrying out operations of the present technology may include assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer-readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer-readable program instructions by utilizing state information of the computer-readable program instructions to personalize the electronic circuitry, in order to perform aspects of the present technology.

Aspects of the present technology are described herein with reference to flowchart illustrations and/or block diagrams of methods, apparatus (systems), and computer program products according to embodiments of the technology. It will be understood that each block of the flowchart illustrations and/or block diagrams, and combinations of blocks in the flowchart illustrations and/or block diagrams, can be implemented by computer-readable program instructions.

These computer-readable program instructions may be provided to a processor of a general-purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer-readable program instructions may also be stored in a computer-readable storage medium that can direct a computer, a programmable data processing apparatus, and/or other devices to function in a particular manner, such that the computer-readable storage medium having instructions stored therein comprises an article of manufacture including instructions which implement aspects of the function/act specified in the flowchart and/or block diagram block or blocks.

The computer-readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

Many of the functional units described in this specification have been labeled as modules, in order to more particularly emphasize their implementation independence. For example, a module may be implemented as a hardware circuit comprising custom VLSI circuits or gate arrays, off-the-shelf semiconductors such as logic chips, transistors, or other discrete components. A module may also be implemented in programmable hardware devices such as field programmable gate arrays, programmable array logic, programmable logic devices or the like.

Modules may also be implemented in software for execution by various types of processors. An identified module of program instructions may, for instance, comprise one or more physical or logical blocks of computer instructions that may, for instance, be organized as an object, procedure, or function. Nevertheless, the executables of an identified module need not be physically located together, but may comprise disparate instructions stored in different locations which, when joined logically together, comprise the module and achieve the stated purpose for the module.

Furthermore, the described features, structures, or characteristics of the embodiments may be combined in any suitable manner. In the following description, numerous specific details are provided, such as examples of programming, software modules, user selections, network transactions, database queries, database structures, hardware modules, hardware circuits, hardware chips, etc., to provide a thorough understanding of embodiments. One skilled in the relevant art will recognize, however, that embodiments may be practiced without one or more of the specific details, or with other methods, components, materials, and so forth. In other instances, well-known structures, materials, or operations are not shown or described in detail to avoid obscuring aspects of an embodiment.

The schematic flowchart diagrams and/or schematic block diagrams in the Figures illustrate the architecture, functionality, and operation of possible implementations. It should also be noted that, in some alternative implementations, the functions noted in the block may occur out of the order noted in the Figures. For example, two blocks shown in succession may, in fact, be executed substantially concurrently, or the blocks may sometimes be executed in the reverse order, depending upon the functionality involved. Although various arrow types and line types may be employed in the flowchart and/or block diagrams, they are understood not to limit the scope of the corresponding embodiments. Indeed, some arrows or other connectors may be used to indicate only an exemplary logical flow of the depicted embodiment.

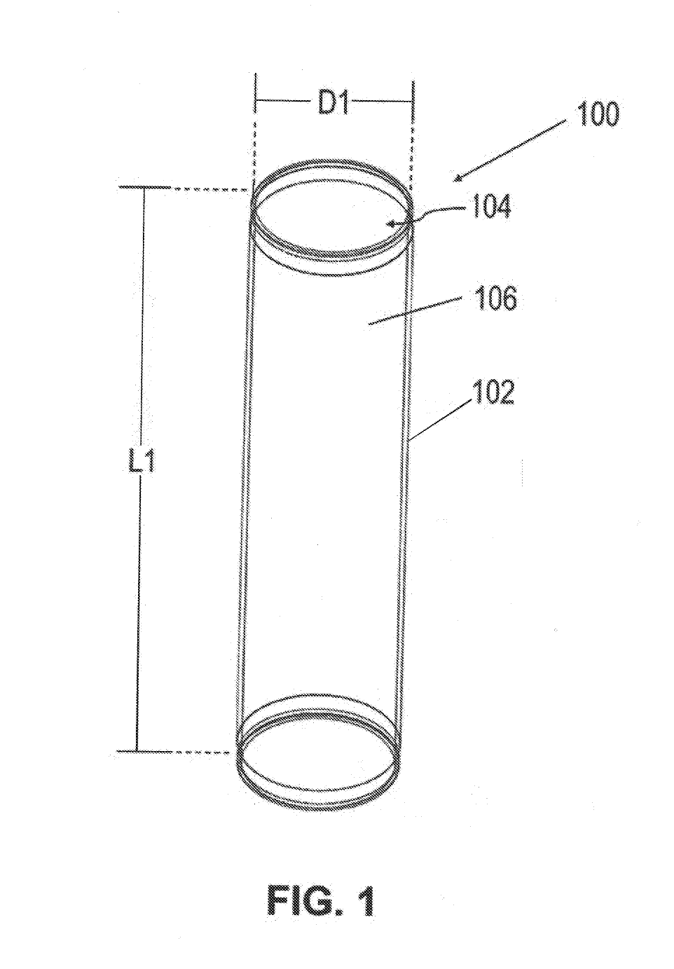

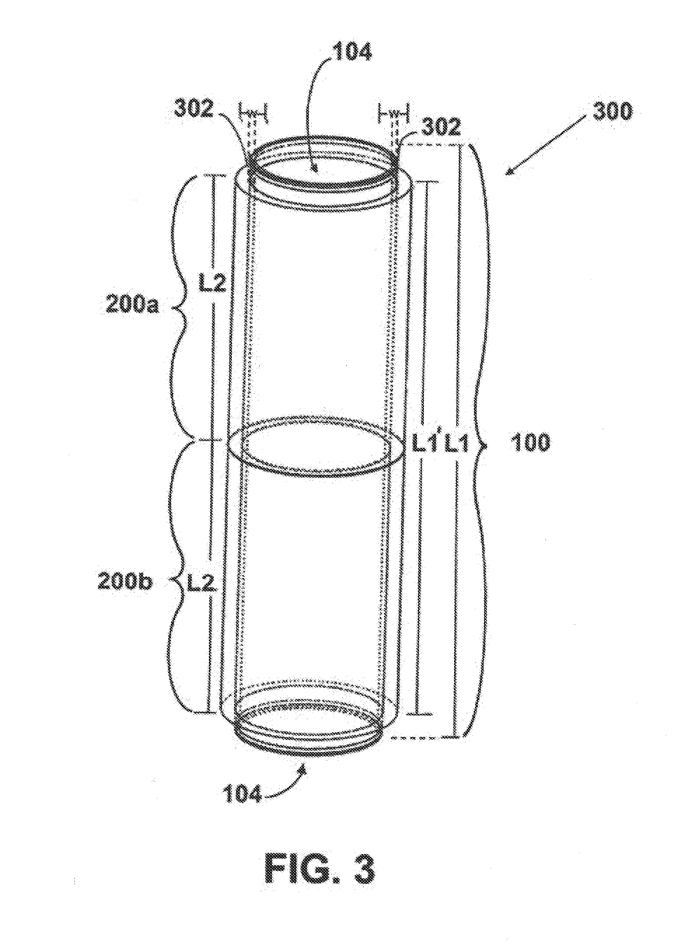

Turning now to the figures, FIG. 1 is a diagram of one embodiment of a mandrel 100. A mandrel 100 may be any mandrel that is known or developed in the future that can form at least at portion of a PVD mandrel-target assembly 300 (see FIG. 3) and at least assist in. In some embodiments, a mandrel 100 may be a mandrel manufactured by ProTech Materials, Inc. of Hayward, Calif., among other manufacturers and/or sources of mandrels that are possible and contemplated herein.

A mandrel 100 may comprise any suitable material that is known or developed in the future that is capable of transferring/transporting heat. In various embodiments, a mandrel 100 comprises one or more thermally conductive materials, thermally semi-conductive materials, and/or other type(s) of material that is/are capable of transferring/transporting heat. Some non-limiting examples of a suitable material include, but are not limited to, a metal, an alloy, a carbon, a ceramic, a composite, a polymer-based material, a silicate-based material, acrylic glass, diamond, fiberglass (e.g., transparent conductive oxides), indium tin-nitride oxide, aluminum doped zinc oxide, polystyrene, manganese, marble, Teflon™, graphene, graphite, and/or the like material(s), etc., among other materials that are possible and contemplated herein. Non-limiting examples of a metal/alloy include, but are not limited to, aluminum (Al), aluminum nitride, aluminum oxide, Ammonia, Argon, Beryllium oxide, Bismuth, Brass CU63%, Brass Cu70%, Bronze, Calcium silicate, Carbon dioxide, Cerium dioxide, Copper, Iron, Lead, Nickel, Molybdenum, Invar, Kovar, Perlite, Solder, Steel, Thorium dioxide, Tin, Zinc, Zinc oxide, Zirconium dioxide, gold (Au), silver (Ag), copper (Cu), cobalt (Co), tungsten (W), titanium (Ti), stainless steel, and/or the like metals/alloys, etc., among other metals/alloys that are possible and contemplated herein. Additionally, or alternatively, a material may be selected so that the mandrel 100 may be heated to a predetermined temperature during assembly of a PVD mandrel-target assembly 300, as discussed elsewhere herein.

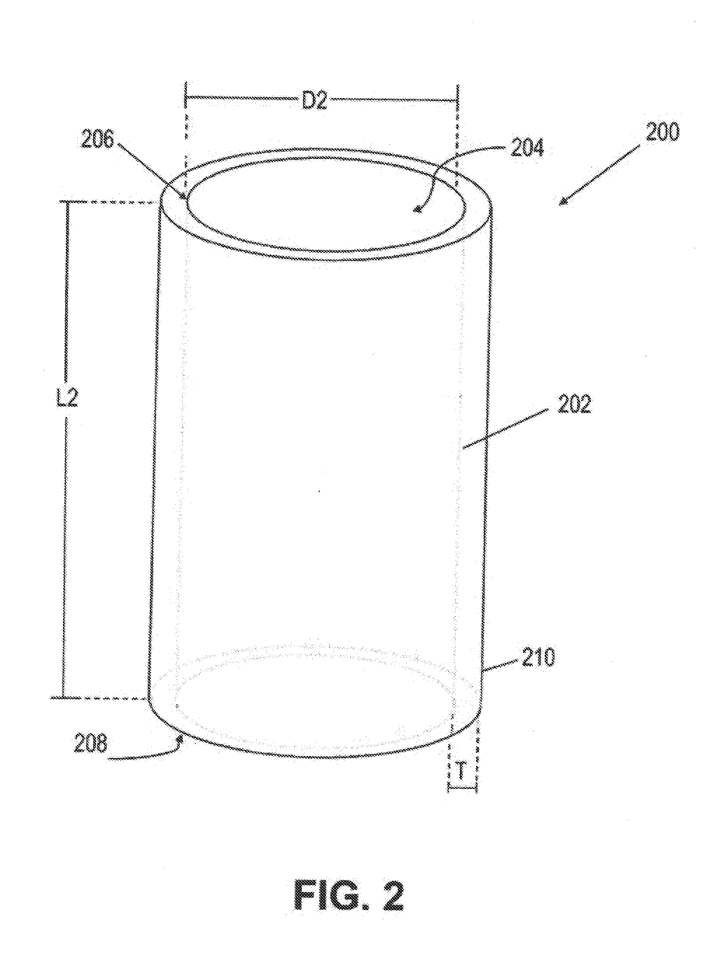

In various embodiments, a mandrel 100 may include any suitable shape that is known or developed in the future that can reside within a hollow portion of a PVD target (e.g., hollow portion 204 of PVD target 200 in FIG. 2). At least in the illustrated embodiment, the mandrel 100 includes a generally cylindrical shape with a length L1 and an overall diameter D1. A mandrel 100 further includes an exterior surface 102 and a hollow portion 104 therein (although solid and/or semi-solid structures, etc., are also possible for embodiments that may be void of an internal heater 412) that extends along the length L1 and is defined by an interior surface 106.

The length L1 of a mandrel 100 may be any suitable length that enables the mandrel 100 to be coupled to and/or combined with one or more PVD targets 200 (e.g., see FIG. 2) to form a PVD mandrel-target assembly 300, as shown in FIG. 3 and discussed elsewhere herein. In some embodiments, the length L1 is in the range of about 85 cm to about 386 cm, although other lengths and/or ranges are possible and contemplated herein. In one embodiment, the length L1 is about 165 cm.

The diameter D1 of the mandrel 100 may be any suitable diameter that enables the mandrel 100 to be housed within one or more PVD targets 200, as discussed elsewhere herein. For instance, one or more PVD targets 200 may be placed around/over the mandrel 100 to cover one or more portions of the exterior surface 102 along the length L1, as discussed elsewhere herein. In some embodiments, the diameter D1 is in the range of about 10 cm to about 16 cm, although other diameters and/or ranges are possible and contemplated herein. In one embodiment, the diameter D1 is about 13.25 cm.

While the diameter D1 is discussed in singular terms, one skilled in the art would recognize that the diameter D1 could exist in two planes/axes (e.g., x-axis and y-axis) to create a pair of lateral dimensions with L1 being a vertical dimension (e.g., z-axis). Furthermore, for non-circular shapes, the diameter D1 can represent lengths along both the x-axis and y-axis, and can be the same length or different lengths depending on the shape and/or application of the mandrel 100.

A mandrel 100 includes a material thickness between the exterior surface 102 and the interior surface 106. The material thickness may be any suitable thickness that enables the mandrel 100 to be heated to a predetermined temperature during assembly of a PVD mandrel-target assembly 300, as discussed elsewhere herein.

With reference to FIG. 2, FIG. 2 is a diagram that illustrates one embodiment of a PVD target 200. A PVD target 200 may be any target that is known or developed in the future that can form at least at portion of a PVD mandrel-target assembly 300 (see FIG. 3). In some embodiments, a PVD target 200 may be a target manufactured by ProTech Materials, Inc. of Hayward, Calif., among other manufacturers and/or sources of targets that are possible and contemplated herein.

A PVD target 200 may comprise any suitable material that is known or developed in the future that can transform from a condensed phase to a vapor phase during a PVD process (e.g., sputtering, evaporation, etc.). Some non-limiting examples of a suitable material include, but are not limited to, a metal, an alloy, a carbon, a ceramic, a composite, a polymer-based material, a silicate-based material, acrylic glass, diamond, fiberglass (e.g., transparent conductive oxides), indium tin-nitride oxide, aluminum doped zinc oxide, polystyrene, manganese, marble, Teflon™, graphene, graphite, and/or the like material(s), etc., among other materials that are possible and contemplated herein. Non-limiting examples of a metal/alloy include, but are not limited to, Al, Au, Ag, Cu, Co, W, Ti, aluminum nitride, aluminum oxide, Ammonia, Argon, Beryllium oxide, Bismuth, Brass CU63%, Brass Cu70%, Bronze, Calcium silicate, Carbon dioxide, Cerium dioxide, Copper, Iron, Lead, Nickel, Molybdenum, Invar, Kovar, Perlite, Solder, Steel, Thorium dioxide, Tin, Zinc, Zinc oxide, Zirconium dioxide, stainless steel, and/or the like metals/alloys, etc., among other metals/alloys that are possible and contemplated herein.

A PVD target 200 may include any suitable shape that is known or developed in the future that can assist in having material uniformly removed from the PVD target 200 during a PVD process. At least in the illustrated embodiment, the PVD target 200 includes a generally cylindrical shape with an interior surface 202 defining a hollow portion 204 along a length L2 with top and bottom apertures 206 and 208, respectively, including a diameter D2.

The length L2 of the PVD target 200 may be any suitable length that enables the one or more PVD targets 200 to be combined with a mandrel 100 to form a PVD mandrel-target assembly 300, as shown in FIG. 3 and discussed elsewhere herein. In various embodiments, the length L2 is less than the length L1 of a mandrel 100. For instance, the length L2 is less than the length L1 so that a PVD mandrel-target assembly 300 comprises one or more PVD targets 200 and a mandrel 100, as discussed elsewhere herein.

In some embodiments, the length L2 is in the range of about 20 cm to about 31 cm, although other lengths and/or ranges are possible and contemplated herein. In one embodiment, the length L2 is about 25 cm.

The diameter D2 may be any suitable diameter that enables a mandrel 100 to be housed within the hollow portion 204. For instance, the hollow portion 204 of one or more PVD targets 200 may be placed over a mandrel 100 such that the PVD target(s) 200 cover one or more portions of the exterior surface 102 along the length L1. In some embodiments, the diameter D2 is in the range of about 13 cm to about 14 cm, although other diameters and/or ranges are possible and contemplated herein. In one embodiment, the diameter D2 is about 13.48 cm.

While the diameter D2 is discussed in singular terms, one skilled in the art would recognize that the diameter D2 could exist in two planes/axes (e.g., x-axis and y-axis) to create a pair of lateral dimensions with L2 being a vertical dimension (e.g., z-axis). Furthermore, for non-circular shapes, the diameter D2 can represent lengths along both the x-axis and y-axis, and can be the same length or different lengths depending on the shape and/or application of the PVD target 200.

A PVD target 200 includes an exterior surface 210 that defines a thickness T between the exterior surface 210 and the interior surface 202. The thickness T may be any suitable thickness that enables the PVD target 200 to provide material during a PVD process. Additionally, or alternatively, the thickness T may be selected so that a PVD target 200 may be heated to a predetermined temperature during assembly of a PVD mandrel-target assembly 300, as discussed elsewhere herein.

Referring now to FIG. 3, FIG. 3 is a diagram illustrating one embodiment of a PVD mandrel-target assembly 300. At least in the illustrated embodiment, the PVD mandrel-target assembly 300 includes one (1) mandrel 100 and two (2) PVD targets 200a and 200b (also simply referred to individually, in various groups, or collectively, as PVD target(s) 200), although other quantities of PVD targets 200 are possible and contemplated herein. For instance, other embodiments of the PVD mandrel-target assembly 300 may include one (1) PVD target 200 or three (3) or more PVD targets 200 such that the PVD mandrel-target assembly 300 is not limited to two (2) PVD targets 200.

In various embodiments, the PVD mandrel-target assembly 300 includes a gap 302 or space between the mandrel 100 and each of the PVD targets 200 that extends along the length of each L2 and a portion L1′ of length L1 that is covered by the PVD targets 200. A gap 302 is created by the difference between the overall diameter D1 of a mandrel 100 and the diameter D2 of the hollow portion 204 of each PVD target 200.

The width W of the gap 302 may be any suitable width than allows the PVD targets 200 to fit around/over the mandrel 100. In various embodiments, the width W is in the range of about 1 mm to about 2 mm, although other ranges and/or widths are possible and contemplated herein. In one embodiment, the maximum width W of the gap 302 is about 2 mm.

A gap 302, in various embodiments, can be filled with an adhesive material that is utilized to couple, connect, and/or bond the mandrel 100 and the PVD target(s) 200 to create a PVD mandrel-target assembly 300. The adhesive material may be any material that is known or developed in the future that can suitably couple/connect/bond the mandrel 100 and the PVD target(s) 200 to one another. Non-limiting examples of an adhesive material include, but are not limited to, a glue, an epoxy, a paste, solder, ethylene vinyl acetate, ultrasonic, and/or indium, etc., although other adhesive materials are possible and contemplated herein. In one embodiment, the adhesive material is indium.

In some embodiments, a mandrel 100 and the PVD target(s) 200 comprise the same material or substantially similar materials. In other embodiments, the mandrel 100 and the PVD target(s) 200 comprise different materials.

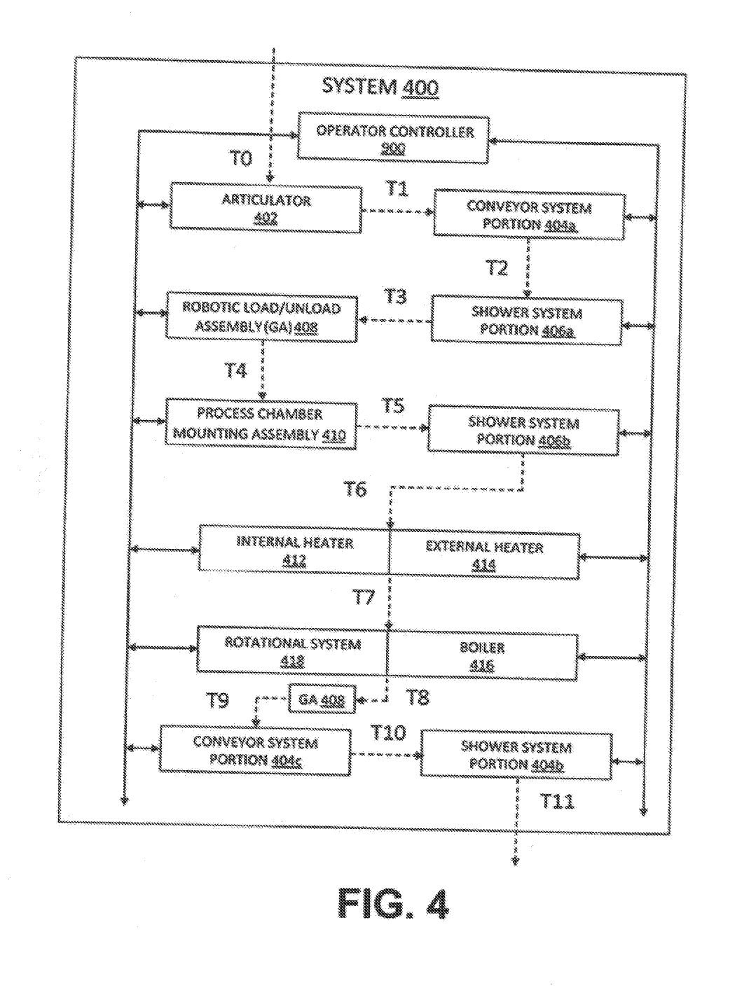

FIG. 4 is a block diagram of one embodiment of a system 400 for creating a PVD mandrel-target assembly 300. At least in the illustrated embodiment, the system 400 includes, among other components, an articulator 402, a conveyor system 404, a shower system 406, a robotic load/unload assembly 408, a process chamber mounting assembly 410, an internal heater 412, an external heater 414, a boiler 416, a rotational system 416, and an operator controller 900.

An articulator 402 may be any articulator that is known or developed in the future. In various embodiments, an articulator 402 may be located proximate to a first staging area that at least temporarily stores mandrels 100 and PVD targets 200 and can selectively provide/place the mandrels 100 and PVD targets 200 on the conveyor system 404. In some embodiments, an articulator 402 can selectively provide/place the mandrels 100 and PVD targets 200 on the conveyor system 404 in a predetermined pattern and/or order. For instance, for a PVD mandrel-target assembly 300 that includes a mandrel 100 and two (2) PVD targets 200, the articulator 402 can selectively provide the mandrel 100 and PVD targets 200 to the conveyor system 404 in a PVD mandrel-target-target pattern, a target-target-mandrel pattern, or a target-mandrel-target pattern, among other examples that may include one (1) PVD target 200 or more than two (2) PVD targets 200.

A conveyor system 404 may be any apparatus, device, and/or system that can transport mandrels 100, PVD targets 200, and PVD mandrel-target assemblies 300 to/from various components of the system 400 and/or various locations. In some embodiments, a conveyer system 404 includes a belt, a chain, a wire, a rope, rollers, and/or other type of transport mechanism, etc., among other possibilities that are contemplated herein.

At least in the illustrated embodiment, the conveyor system 404 comprises conveyor system portions 404a and 404b, although other portion quantities are possible and contemplated herein such that the conveyor system 404 may include fewer or greater portion quantities and is not limited to two (2) portions. A conveyor system portion 404a receives the mandrels 100 and PVD targets 200 from the articulator 402 and provides the mandrels 100 and PVD targets 200 to a shower system portion 406a and/or to the robotic load/unload assembly 408.

In some embodiments, a conveyor system portion 404a includes one or more boots or other suitable device(s)/structure(s) that can prevent or substantially prevent mandrels 100 and PVD targets 200 from moving around and/or off the conveyor system portion 404a. A boot may include any suitable shape, size dimension(s), and/or material that would immobilize or substantially immobilize the mandrels 100 and PVD targets 200 while on the conveyor system portion 404a.

In some embodiments, a boot may include a tapered, conical, or substantially tapered/conical shape that extends vertically and comprises silicon, although other shapes and/or materials are possible and contemplated herein. For instance, a tapered/conical shape may include a height that can accommodate both the hollow portion 104 of a mandrel 100 and the hollow portion 204 of a PVD target 200. In other words, a tapered/conical shape can accommodate multiple types of device that may include diameters with different sizes (e.g., is sized to accommodate D1 and D2 even though D1 is smaller than D2).

A conveyor system portion 404b receives PVD mandrel-target assemblies 300 from a robotic load/unload assembly 408 and provides the PVD mandrel-target assemblies 300 to a shower system portion 406b and/or to a second staging area that can store the PVD mandrel-target assemblies 300. In some embodiments, a conveyor system portion 404b includes a boot or other suitable device/structure that prevents or substantially prevents PVD mandrel-target assemblies 300 from moving around and/or off the conveyor system portion 404b.

A boot of a conveyor system portion 404b may include any suitable shape, size dimension(s), and/or material that would immobilize or substantially immobilize the PVD mandrel-target assemblies 300 while on the conveyor system portion 404b. In some embodiments, the boot(s) includes a tapered, conical, or substantially tapered/conical shape and comprise silicon similar to the boot(s) discussed above with reference to conveyor system portion 404a, although the dimensions of the boot(s) on the conveyor system portion 404b may be based on the diameter D1 of the hollow portion 104 of the mandrel 100 since the PVD mandrel-target assemblies 300 include the PVD target(s) 200 coupled to the exterior surface 102 of the mandrel 100 and are not separately accommodated on the conveyor system portion 404b.

A shower system 406 may be any system, device, and/or apparatus that is/are known or developed in the future that can reduce the exposure of mandrels 100, PVD targets 200, and/or PVD mandrel-target assemblies 300 to moisture and/or humidity to reduce, prevent, and/or substantially reduce/prevent oxidation of the mandrels 100, PVD targets 200, and/or PVD mandrel-target assemblies 300. In various embodiments, a shower system 406 applies, sprays, or otherwise facilitates contact between the mandrels 100, PVD targets 200, and/or PVD mandrel-target assemblies 300 and one or more suitable materials that can reduce the moisture and/or humidity to reduce, prevent, and/or substantially reduce/prevent oxidation of the mandrels 100, PVD targets 200, and/or PVD mandrel-target assemblies 300. Non-limiting examples of suitable materials include, but are not limited to, nitrogen (N), argon (Ar), etc., although other suitable materials are possible and contemplated herein. In one embodiment, the material is nitrogen such that the shower system 406 facilitates/provides a nitrogen shower.

At least in the illustrated embodiment, the shower system 406 includes shower system portions 406a, 406b, and 406c, although other portion quantities are possible and contemplated herein such that the shower system 406 may include fewer or greater portion quantities and is not limited to three (3) portions. In some embodiments, a shower system 406 includes each of the shower system portions 406a, 406b, and 406c. In other embodiments, a shower system 400 includes two (2) of the shower system portions 406a, 406b, and 406c. In further embodiments, a shower system 406 includes one of the shower system portions 406a, 406b, and 406c.

A shower system portion 406a may be located and/or include a structure that allows the shower system portion 4006a to receive mandrels 100 and PVD targets 200 via the conveyor system portion 404a and apply, shower, or otherwise expose the mandrels 100 and PVD targets 200 to the suitable material (e.g., nitrogen, etc.) while the mandrels 100 and PVD targets 200 are being transported by the conveyor system portion 404a. A shower system portion 406b may be located and/or include a structure that allows the shower system portion 4006b to apply, shower, or otherwise expose the mandrels 100 and PVD targets 200 to the suitable material (e.g., nitrogen, etc.) while the mandrels 100 and PVD targets 200 are mounted on a process chamber mounting assembly 410, as discussed below. A shower system portion 406c may be located and/or include a structure that allows the shower system portion 4006c to receive PVD mandrel-target assemblies 300 via the conveyor system portion 404b and apply, shower, or otherwise expose the PVD mandrel-target assemblies 300 to the suitable material (e.g., nitrogen, etc.) while the PVD mandrel-target assemblies 300 are being transported by the conveyor system portion 404b.

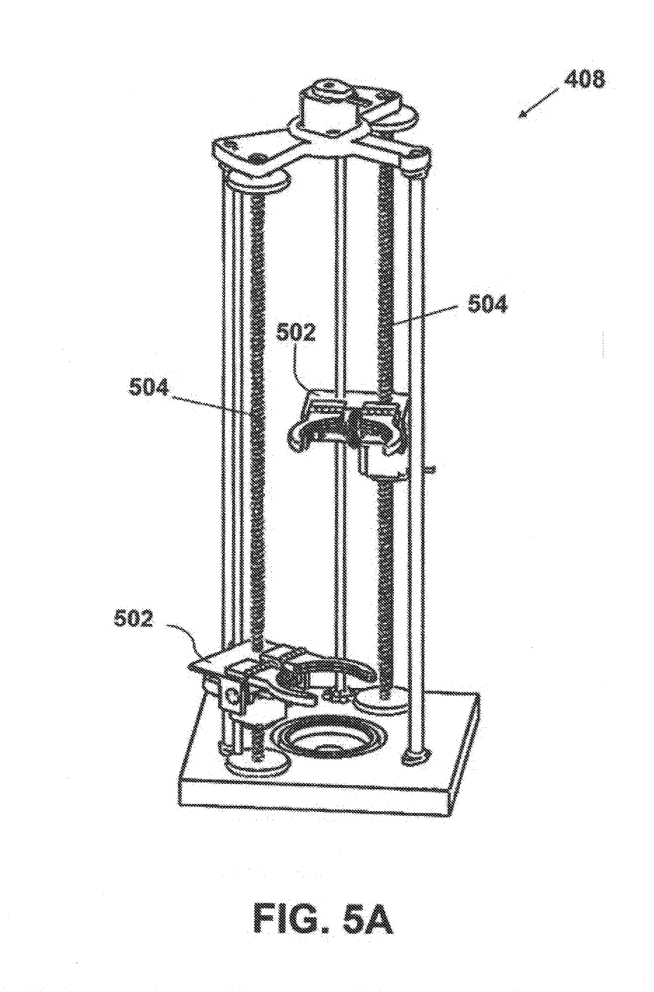

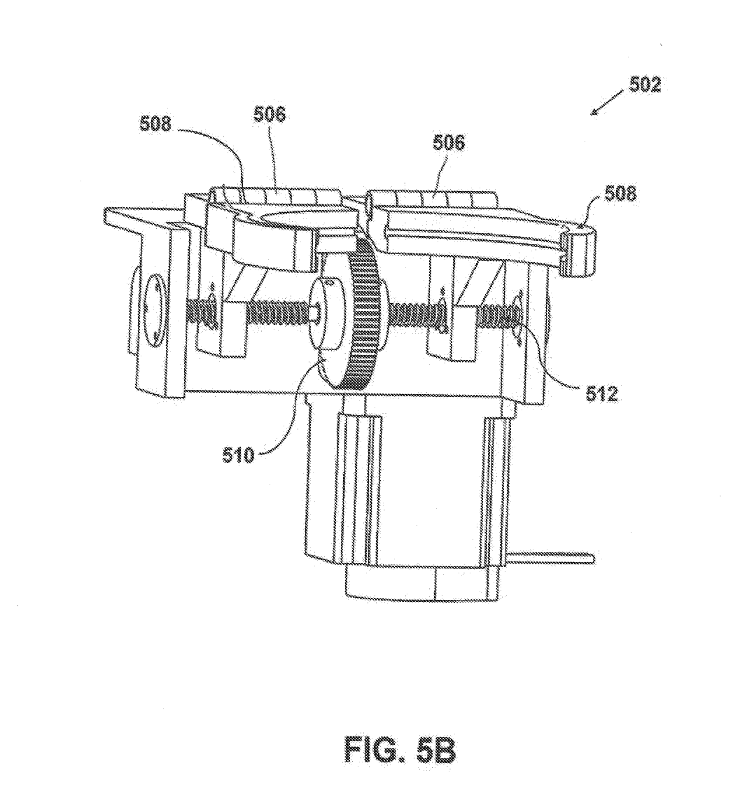

With reference to FIG. 5A, FIG. 5A is a diagram of one embodiment of a robotic load/unload assembly 408 that can be located proximate to the conveyor system 404 or portion 404a thereof. A robotic load/unload assembly 408, in various embodiments, may include one or more hinge-grasp systems 502 coupled to a respective elevator system 504. At least in the illustrated embodiment, the robotic load/unload assembly 408 includes two (2) hinge-grasp systems 502 and two (2) elevator systems 504, although quantities are possible and contemplated herein such that the robotic load/unload assembly 408 may include fewer or greater quantities of hinge-grasp systems 502 and elevator systems 504 and is not limited to two (2) hinge-grasp systems 502 and elevator systems 504.

A hinge-grasp system 504 may include one or more hinging mechanisms/structures and one or more grasping mechanisms/structures. The hinging mechanism(s) may include any suitable type of mechanism/structure that is known or developed in the future that can move with at least four (4) degrees of freedom (e.g., movement on and around an x-axis and a y-axis). Non-limiting suitable hinging mechanisms include, but are not limited to a wrist, a joint, and/or an elbow, etc., although other mechanisms/structures are possible and contemplated herein. In one embodiment, the hinging mechanism is a wrist.

The grasping mechanism(s) may include any suitable type of mechanism/structure that is known or developed in the future that can grasp an object (e.g., mandrels 100, PVD targets 200, sputter-target assemblies 300, etc.). Non-limiting suitable grasping mechanisms include, but are not limited to, a clamp, a claw, a hand, etc., although other mechanisms/structures are possible and contemplated herein. In one embodiment, the grasping mechanism is a clamp.

An elevator system 504 may be any system, device, and/or apparatus that is known or developed in the future that can move a hinge-grasp system 504 with at least two (2) degrees of freedom (e.g., on or around a z-axis). At least in the illustrated embodiment, the elevator system 504 includes a threaded pole or post upon which a hinge-grasp system 504 can be coupled and/or mounted, although other mechanisms and/or structures are possible and contemplated herein.

A robotic load/unload assembly 408, in various embodiments, may include six (6) degrees of freedom such that an object (e.g., mandrels 100, PVD targets 200, sputter-target assemblies 300, etc.) held by a gasping mechanism can be moved along and/or rotated around an x-axis, y-axis, and z-axis. A robotic load/unload assembly 408, in some embodiments can grasp mandrels 100 and PVD targets 200 on a conveyor system 404 or portion 404a thereof, transport the mandrels 100 and PVD targets 200 to a process chamber mounting assembly 410, and place the mandrels 100 and PVD targets 200 on the process chamber mounting assembly 410 in preparation for creating a PVD mandrel-target assembly 300. In additional or alternative embodiments, a robotic load/unload assembly 408 can grasp PVD mandrel-target assemblies 300 on a process chamber mounting assembly 410, transport the PVD mandrel-target assemblies 300 to a conveyor system 404 or portion 404b thereof, and place the PVD mandrel-target assemblies 300 on the conveyor system 404 or portion 404b thereof.

Referring to FIG. 5B, FIG. 5B is a diagram of one embodiment of a hinge-grasp system 502 of the robotic load/unload assembly 408. At least in the illustrated embodiment, the hinging mechanism includes one or more wrists 506 or portions thereof coupled to one another and the grasping mechanism includes one or more clamps 508 or portions thereof coupled to one another, each of which may comprise any suitable material (e.g., a metal, an alloy, a composite material, etc.). The hinge-grasp system 502 further includes a cog 510 coupled to the wrist(s) 506 and/or clamp(s) 508 to control the movement of the wrist(s) 506 and/or clamp(s) 508. A threaded pole 512 transverses and/or extends through the center of the cog 510 and can rotate the cog 510, which in turn can cause the wrist(s) 506 and/or clamp(s) 508 to move, open/close, etc. In some embodiments, the threaded pole 512 is reverse threaded, while in other embodiments the threaded pole 512 may be forward threaded.

A process chamber mounting assembly 410 can be located proximate and/or movable to a robotic load/unload assembly 408 and may include any suitable shape, structure and/or mechanism that is known or developed in the future that can provide a platform and/or foundation upon which mandrels 100 and PVD targets 200 can be placed during assembly of PVD mandrel-target assemblies 300. For instance, a process chamber mounting assembly 410 may provide a firm or solid base upon which a mandrel 100 may be placed and one or more PVD targets 200 place over and/or around the mandrel 100. The process chamber mounting assembly 410 may include any suitable shape with dimensions that are larger than the overall diameter or lateral dimensions of the PVD target(s) 200.

In some embodiments, a process chamber mounting assembly 410 includes one or more protrusions or other suitable device(s)/structure(s) that can prevent or substantially prevent mandrels 100, PVD targets 200, and/or PVD mandrel-target assemblies 300 from moving around and/or off the conveyor system portion 404a. A protrusion may include any suitable shape, size dimension(s), and/or material that would immobilize or substantially immobilize the mandrels 100, PVD targets 200, and/or PVD mandrel-target assemblies 300 while on a process chamber mounting assembly 410, especially as the process chamber mounting assembly 410 is being rotated and/or moved by the rotational system 418, as discussed below.

An internal heater 412 can be located proximate and/or movable to a process chamber mounting assembly 410 and may include any suitable structure and/or mechanism that can generate and transport heat to an object (e.g., a mandrel 100) on the process chamber mounting assembly 410. Further, an internal heater 412 may include any suitable shape with dimensions that allows the internal heater 412 to be placed within the hollow portion 104 of a mandrel 100.

In various embodiments, an internal heater 412 can generate an amount of heat and/or is heated to a temperature in the range of about 156° C. to about 177° C., although other ranges and/or temperatures are possible and contemplated herein. In one embodiment, the internal heater 412 generates and/or is heated to a temperature of about 156.6° C.

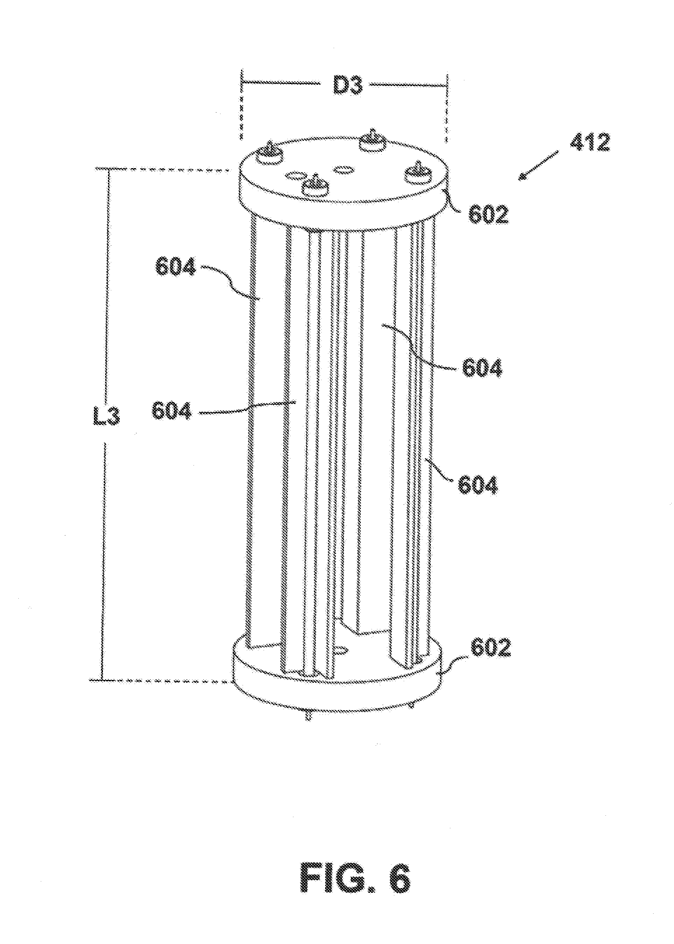

Referring now to FIG. 6, FIG. 6 is a diagram of one embodiment of an internal heater 412 that can be located proximate and/or movable to a process chamber mounting assembly 410. At least in the illustrated embodiment, the internal heater 412 may include a pair of base plates 602 with a set of heating elements 604 coupled to and extending between the pair of base plates 602, although other structures and/or mechanisms are possible and contemplated herein. As shown, the internal heater 412 includes four (4) heating elements 604, although other quantities of heating elements 604 are possible and contemplated herein such that an internal heater 412 may include fewer or greater quantities of heating elements 604 and is not limited to four (4) heating elements 604. In some embodiments, a heating element 604 may be a heating rod and/or another suitable device/structure that can generate and transport heat to the interior surface 106 of a mandrel 100.

The illustrated internal heater 412 includes a generally cylindrical shape that may correspond to the shape of the hollow portion 104 of a mandrel 100, although other suitable shapes are possible and contemplated herein. The internal heater 412 further includes a diameter D3 that is less than the diameter of the hollow portion 104 of a mandrel 100 to allow the internal heater 412 to be inserted/placed in the hollow portion 106 and be located proximate to the interior surface 106 of the mandrel 100 to allow heat from the internal heater 412 to be transported to the mandrel 100 via the interior surface 106. In some embodiments, the internal heater 412 includes a diameter D3 that allows the internal heater 412 to be in physical contact with or within a predetermined distance (e.g., less than or equal to about 1 mm) of an interior surface 106 when the internal heater 412 resides in the hollow portion 104 of a mandrel 100. For non-circular shapes, the lateral dimensions (e.g., lengths along an x-axis and a y-axis) of an internal heater 412 are each less than the length of the diameter of a hollow portion 104.

An internal heater 412 includes a length L3 that may be any suitable length that can allow the internal heater 412 to transport heat to the entirety of a mandrel 100 via its interior surface 106 when accommodated within the hollow portion 104 of a mandrel 100. In various embodiments, the length L3 may be a length that is greater than, less than, or equal to the length L1 of a mandrel 100.

An external heater 414 can be located proximate and/or movable to a process chamber mounting assembly 410 and may include any structure and/or mechanism that can generate and transport heat to another object (e.g., a PVD target 200) on the process chamber mounting assembly 410. In various embodiments, an external heater 414 may include any suitable shape and/or structure with dimensions that allows the external heater 414 to be placed over and/or around a PVD target 200.

In various embodiments, an external heater 414 can generate an amount of heat and/or is heated to a temperature in the range of about 156° C. to about 177° C., although other ranges and/or temperatures are possible and contemplated herein. In one embodiment, the external heater 414 generates and/or is heated to a temperature of about 156.6° C. In some embodiments, an external heater 414 generates and/or is heated to the same temperature as an internal heater 412 so that the PVD target(s) 200 and mandrel 100 in thermal communication with the external heater 414 and internal heater 412, respectively, may be heated to the same temperature and/or to corresponding temperatures.

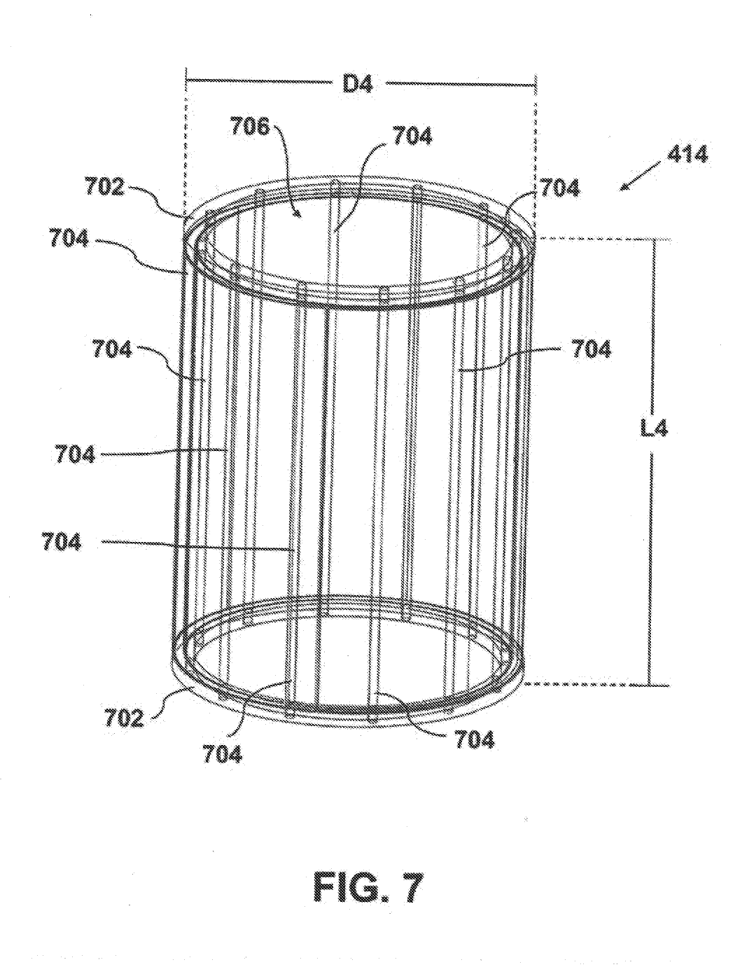

Referring now to FIG. 7, FIG. 7 is a diagram of one embodiment of an external heater 414 that can be located proximate and/or movable to a process chamber mounting assembly 410. At least in the illustrated embodiment, the external heater 414 may include a pair of circular structures, which can be referred to herein as rings 702, with a set of heating elements 704 coupled to and extending between the pair of rings 702 to define a heater cage, although other structures and/or mechanisms are possible and contemplated herein. As shown, the external heater 414 includes twelve (12) heating elements 704, although other quantities of heating elements 704 are possible and contemplated herein such that an external heater 414 may include fewer or greater quantities of heating elements 704 and is not limited to twelve (12) heating elements 704. In some embodiments, a heating element 704 may be a heating rod and/or another suitable device/structure that can generate and transport heat to the exterior surface 210 of a PVD target 200. In additional or alternative embodiments, the external heater 414 includes a heater wrap that can cover/surround at least a subset of the heating elements 704 and/or one or more PVD targets 200 within the hollow portion 706.

The illustrated external heater 414 includes a generally cylindrical shape that may correspond to the overall shape of a PVD target 200, although other suitable shapes are possible and contemplated herein. The external heater 414 further includes a hollow portion 706 with a diameter D4 that is greater than the overall diameter of a PVD target 200 to allow a PVD target 200 (and a mandrel 100 residing within the PVD target 200) to be inserted/placed in the hollow portion 706 and so that the external heater 414 is located proximate to the exterior surface 210 of the PVD target 200 to allow heat from the external heater 414 to be transported to the PVD target 200 via the exterior surface 210. In some embodiments, the hollow portion 706 includes a diameter D4 that allows the internal heater 412 to be in physical contact with or within a predetermined distance (e.g., less than or equal to about 1 mm) of an exterior surface 210 of a PVD target 200 when the external heater 414 covers/surrounds the PVD target 200. For non-circular shapes, the lateral dimensions (e.g., lengths along an x-axis and a y-axis) of an external heater 414 are each greater than the length of the diameter D4 of a hollow portion 706.

An external heater 412 includes a length L4 that may be any suitable length that can allow the external heater 414 to transport heat to the entirety of a PVD target 200 via its exterior surface 210 when covering/surrounding a PVD target 200. In various embodiments, the length L4 may be a length that is greater than, less than, or equal to the length L2 of one or more PVD targets 200 and/or the length L1 of a mandrel 100.

A boiler 416 can be located proximate and/or movable to a process chamber mounting assembly 410 and may include any structure and/or mechanism that can generate and transport heat to a material (e.g., an adhesive material) stored in the boiler 416 and provide the heated material to one or more other objects (e.g., a mandrel 100 and/or PVD target 200) on the process chamber mounting assembly 410. In various embodiments, a boiler 416 may include any suitable shape with dimensions that allow the boiler 416 to store, heat, and provide the heated material to the other object(s).

In various embodiments, a boiler 416 can generate an amount of heat and/or is heated to a temperature in the range of about 156° C. to about 177° C., although other ranges and/or temperatures are possible and contemplated herein. In one embodiment, the boiler 416 generates and/or is heated to a temperature of about 156.6° C. In various embodiments, a boiler 416 generates and/or is heated to the same temperature as an internal heater 412 and/or external heater 414 so that an adhesive material stored therein may be heated to the same temperature and/or to a temperature corresponding to a heated and/or pre-heated mandrel 100 and/or one or more heated and/or pre-heated PVD target(s) 200.

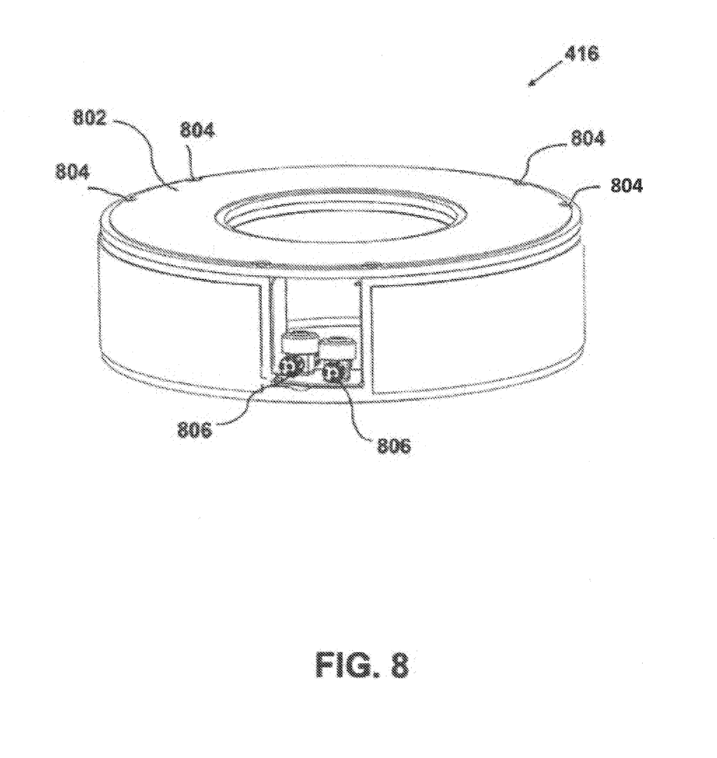

Referring now to FIG. 8, FIG. 8 is a diagram of one embodiment of a boiler 416 that can be located proximate and/or movable to a process chamber mounting assembly 410. At least in the illustrated embodiment, the boiler 416 may include a generally circular shape and/or a hollow structure that defines a reservoir 802 that can store an adhesive material, although other shapes are possible and contemplated herein.

A reservoir 802 may include any amount of storage space that allows an amount of adhesive material to be stored therein. The amount of adhesive material that can be stored in the reservoir may be selectively greater than, less than, or equal to an amount of adhesive material that would fill or substantially fill a gap 302 and/or an amount that would allow the PVD target(s) 200 to be coupled/connected/bonded to a mandrel 100.

The boiler 416 further includes a set of heating elements 804 distributed around the reservoir 802 and in thermal communication with the adhesive material stored therein, although other locations and/or positions are possible and contemplated herein. As shown, the boiler 416 includes four (4) heating elements 804, although other quantities of heating elements 804 are possible and contemplated herein such that a boiler 416 may include fewer or greater quantities of heating elements 804 and is not limited to four (4) heating elements 804. In some embodiments, a heating element 804 may be a heating rod and/or another suitable device/structure that can generate and transport heat to the material in the reservoir 802. In additional or alternative embodiments, the boiler 416 includes a heater wrap that can cover/surround at least a portion of the reservoir 802.

The illustrated boiler 416 further includes a set of applicators 806 that are removably and/or in movable fluid communication with the gap 302 of a PVD mandrel-target assembly 300 and in fluid communication with the reservoir 802. An applicator 806 may be any system, device, and/or apparatus that is known or developed in the future capable of delivering the adhesive material in the reservoir 802 to at least a portion of the gap 302 of a PVD mandrel-target assembly 300. In some embodiments, an applicator 806 may include a structure/system that provides the adhesive material to a gap 302 utilizing gravity to define a gravity-fed structure/system and/or may include a structure/system that provides the adhesive material utilizing pressure to define a pressure-fed structure/system or a gravity-pressure-fed structure/system.

As shown, the boiler 416 includes two (2) applicators 806, although other quantities of applicators 806 are possible and contemplated herein such that a boiler 416 may include fewer or greater quantities of applicators 806 and is not limited to two (2) applicators 806. In some embodiments, the applicators 806 may include the same type of applicator 806. In further embodiments, at least two (2) applicators 806 are different types of applicator 806. For instance, a first applicator 806 may be a gravity-fed applicator 806 and a second applicator 806 may be a pressure-fed applicator 806, among other combinations and/or quantities that are possible and contemplated herein.

A rotational system 418 can be coupled to a process chamber mounting assembly 410 and may include any structure and/or mechanism that can rotate the process chamber mounting assembly 410. A rotational system 418 may rotate the process chamber mounting assembly 410 at any suitable speed or velocity that can create an amount of force on an adhesive material in a gap 302 as the adhesive material is being poured, injected, or otherwise introduced into the gap 302. Further, a rotational system 418 may continuously or substantially continuously rotate the process chamber mounting assembly 410 and/or rotate the process chamber mounting assembly 410 at a constant or substantially constant speed.

In various embodiments, the speed may be in the range of about 10 revolutions-per-minute (RPMs) to about 30 RPMs, although other ranges and/or speeds are possible and contemplated herein. In one embodiment, the speed is about 20 RPMs. A speed may be selected based on a desired and/or needed amount of centrifugal force for a particular application and/or adhesive material.

In some embodiments, the amount of centrifugal force created by the rotational assembly 418 allows the adhesive material to uniformly or substantially uniformly fill the space in the gap 302. In additional or alternative embodiments, the amount of centrifugal force created by the rotational assembly 418 can force air out of the gap 302 while the adhesive material is being poured/introduced into the gap 302.

FIG. 4 further illustrates a timing diagram for creating a PVD mandrel-target assembly 300. As shown, an articulator 402 can select a mandrel 100 and one or more PVD targets 200 (T0) and provide the mandrel 100 and PVD target(s) 200 to a conveyor system 404 or portion 404a thereof in a predetermined pattern for transport to other components and/or locations in the system 400 (T1).

The mandrel 100 and/or PVD target(s) 200 may be presented to a shower system 406 or portion thereof 406a (T2) to be exposed to, for example, nitrogen or other suitable material, as discussed elsewhere herein. At T3, a robotic load/unload assembly 408 retrieves the mandrel 100 and PVD target(s) 200 and mounts them on a process chamber mounting assembly 410 (T4) such that the PVD target(s) 200 cover/surround at least a portion of the mandrel 100. The mandrel 100 and PVD target(s) 200 may initially or additionally be exposed to nitrogen and/or other suitable material in a shower system 404 or portion 406b thereof (T5).

At T6, an internal heater 412 can heat the mandrel 100 to a predetermined temperature and/or an external heater can heat the PVD target(s) 200 to the predetermined temperature, as discussed elsewhere herein. Concurrently and/or subsequent to T6, a rotational assembly 418 can continuously rotate the process chamber mounting assembly 418 with the mandrel 100 and PVD target(s) 200 thereon at a constant speed and/or a 416 can pour or otherwise introduce adhesive material that has be pre-heated to the predetermined temperature into the gap 302 between the mandrel 100 and PVD target(s) 200 (T7), which may subsequently include an amount of time for the adhesive material, mandrel 100, and/or PVD target(s) 200 to cool.

The robotic load/unload assembly 408 can remove the PVD mandrel-target assembly 300 from the process chamber mounting assembly 410 (T8) and present the PVD mandrel-target assembly 300 to a shower system 406 or portion 406c thereof (T9) for initial or additional exposure to nitrogen and/or other suitable material, as discussed elsewhere herein.

The robotic load/unload assembly 408 may then provide the PVD mandrel-target assembly 300 to a conveyor system 404 or portion 404b thereof (T10). The conveyor system 404 or portion 404b may transport the PVD mandrel-target assembly 300 to a second staging area for storage (T11).

An operator controller 900 included in the system 400 can be coupled to and in communication with the various components of the system 400. An operator controller 900 may include any computer hardware or combination of computer hardware/software that can control the various operations of the articulator 402, conveyor system 404, shower system 406, robotic load/unload assembly 408, process chamber mounting assembly 410, internal heater 412, external heater 414, boiler 416, and rotational system 416, as discussed above. Additionally, or alternatively, an operator controller 900 can include any computer hardware or combination of computer hardware/software that can control the timing of the operations of the various components of the system 400 and/or movement of mandrels 100, PVD targets 200, and PVD mandrel-target assemblies 300 through the system 400, as discussed above with reference time T0-T11.

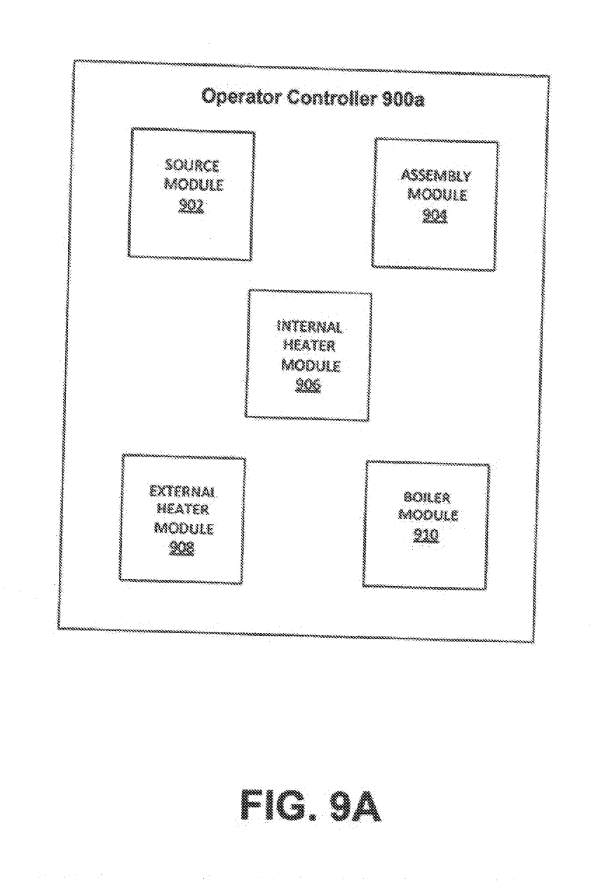

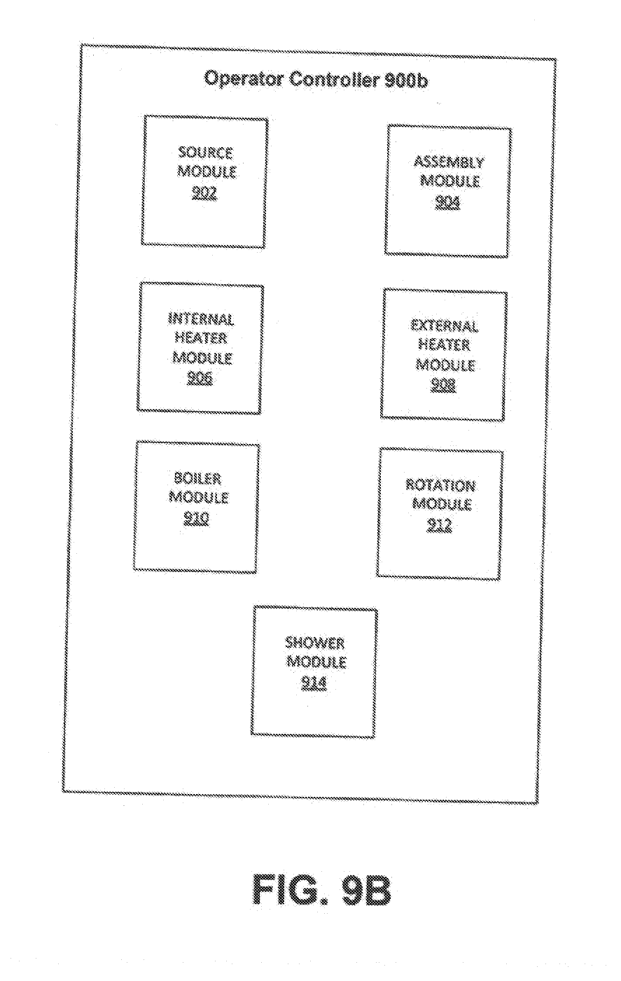

With reference to FIG. 9A, FIG. 9A is a diagram of one embodiment of an operator controller 900a. At least in the illustrated embodiment, the operator controller 900a includes, among other components, a source module 902, an assembly module 904, an internal heater module 906, an external heater module 908, and a boiler module 910.

A source module 902, in various embodiments, may include computer hardware or a combination of computer hardware/software to control the operations and/or timing of the articulator 402, as discussed elsewhere herein. A source module 902 may instruct the articulator 402 to select/arrange mandrels 100 and PVD targets 200 in a predetermined pattern and provide the pattern of mandrel 100 and PVD target(s) to a conveyor system 404 or portion thereof 404a, as discussed elsewhere herein. Further, a source module 902 may control the speed of transport or operational speed of the conveyor system 404 or portion 404a thereof and can switch the conveyor system 404 or portion 404a thereof ON and OFF. In additional or alternative embodiments, a source module 902 may further control a conveyor system 404 or portion 404a thereof to transport the pattern of mandrels 100 and PVD targets 200 to other components and/or locations in the system 400, as discussed elsewhere herein.

In various embodiments, an assembly module 904 may include computer hardware or a combination of computer hardware/software to control the operations and/or timing of the robotic load/unload assembly 408, as discussed elsewhere herein. The assembly module 904, in some embodiments, may instruct the robotic load/unload assembly 408 to retrieve mandrels 100 and PVD targets 200 from a conveyor system 404 or portion 404a thereof and provide the mandrels 100 and PVD targets 200 to a process chamber mounting assembly 410 in the predetermined pattern, as discussed elsewhere herein.

An internal heater module 906, in various embodiments, may include computer hardware or a combination of computer hardware/software to control the operations and/or timing of the internal heater 412, as discussed elsewhere herein. An internal heater module 906 may control the movement of the internal heater 412 into and out of the hollow portion 104 of the mandrel 100. Further, an internal heater module 906 may instruct the internal heater 412 to generate the predetermined amount of heat and/or pre-heat itself to the predetermined temperature, as discussed elsewhere herein.

In various embodiments, an external heater module 908 may include computer hardware or a combination of computer hardware/software to control the operations and/or timing of the external heater 414, as discussed elsewhere herein. An external heater module 908 may control the movement of the external heater 414 onto and off the PVD target(s) 200 that cover/surround a mandrel 100. Further, an external heater module 908 may instruct the external heater 414 to generate the predetermined amount of heat and/or pre-heat itself to the predetermined temperature, as discussed elsewhere herein. Additionally, or alternatively, the external heater module 908 may cooperatively operate and/or operate in conjunction with the internal heater module 906 to pre-heat the PVD target(s) 200 and mandrel 100 to the predetermined temperature at the same time and/or at substantially the same time.

A boiler module 910, in various embodiments, may include computer hardware or a combination of computer hardware/software to control the operations and/or timing of the boiler 416, as discussed elsewhere herein. A boiler module 910 may control the movement of the boiler 416 to and from the gap 302 of the PVD mandrel-target assembly 300. Further, a boiler module 910 may instruct the boiler 416 to pour, inject, or otherwise introduce the adhesive material in its reservoir 802 to the gap 302 between a mandrel 100 and PVD target(s) 200 via its applicator(s) 806, as discussed elsewhere herein.

In various embodiments, a boiler module 910 can instruct a boiler 916 to heat and/or pre-heat the adhesive material in its reservoir 802 to the predetermined temperature, as discussed elsewhere herein. Additionally, or alternatively, the boiler module 908 may cooperatively operate and/or operate in conjunction with the internal heater module 906 and/or the external heater module 908 to heat/pre-heat the adhesive material, PVD target(s) 200 and/or mandrel 100 to the predetermined temperature so that the adhesive material, PVD target(s) 200 and/or mandrel 100 have the same predetermined temperature at the time (e.g., T7 in FIG. 4) the adhesive material is poured, injected, or otherwise introduced into the gap 302.

Referring now to FIG. 9B, FIG. 9B is a diagram of another embodiment of an operator controller 900b. At least in the illustrated embodiment, the operator controller 900b include, among other components, a source module 902, an assembly module 904, and internal heater module 906, an external heater module 908 and a boiler module 910 similar to the operations module 900a. An operations module 900b may further include a rotation module 912 and a shower module 914.

In various embodiments, a rotation module 912 may include computer hardware or a combination of computer hardware/software to control the operations and/or timing of a rotational system 418, as discussed elsewhere herein. A rotation module 912 may instruct the rotational system 418 to begin and end rotating and control the amount of time that the rotational system 418 rotates. Further, a rotation module 912 may control the speed/velocity at which the rotational system 418 rotates and may also ensure that the rotational system 418 rotates at a constant speed and/or is continuously rotated, as discussed elsewhere herein, when the rotational system 418 is ON.

A shower module 914 may include computer hardware or a combination of computer hardware/software to control the operations and/or timing of a shower system 406 or portion(s) 406a, 406b, and/or 406c thereof, as discussed elsewhere herein. A shower module 914 may instruct the shower system 406 to begin and end exposing the mandrels 100, PVD targets 200, and/or PVD mandrel-target assemblies 300 to the nitrogen and/or other suitable material. Further, a shower module 914 may control the amount of time or time duration that the mandrels 100, PVD targets 200, and/or PVD mandrel-target assemblies 300 are exposed to the nitrogen and/or other suitable material. Further, a shower module 914 may monitor and/or control the rate at which the nitrogen is applied/sprayed when the shower system 406 or portions 406a, 406b, and/or 406c is/are ON.

An assembly module 904, in various embodiments, may further include computer hardware or a combination of computer hardware/software to control the operations and/or timing of the robotic load/unload assembly 408. For instance, an assembly module 904 may instruct the robotic load/unload assembly 408 to retrieve a PVD mandrel-target assembly 300 on a process chamber mounting assembly 410 and provide the PVD mandrel-target assembly 300 to a conveyor system 404 or portion 404b thereof, as discussed elsewhere herein.

In some embodiments, a source module 902 may further include computer hardware or a combination of computer hardware/software to control the operations and/or timing of a conveyor system 404 or portion 404b thereof, as discussed elsewhere herein. Further, a source module 902 may instruct a conveyor system 404 or portion 404b thereof to transport PVD mandrel-target assemblies 300 to a staging area for stage. In addition, a source module 902 may control the speed of transport or operational speed of the conveyor system 404 or portion 404b thereof and can switch the conveyor system 404 or portion 404b thereof ON and OFF.

In various embodiments, the operator controller 900, articulator 402, conveyor system 404, shower system 406, robotic load/unload assembly 408, process chamber mounting assembly 410, internal heater 412, external heater 414, boiler 416, and rotational system 416 may form a portion of a computing network. The computing network may be any suitable type of computing network that is known or developed in the future and is capable of enabling the operator controller 900, articulator 402, conveyor system 404, shower system 406, robotic load/unload assembly 408, process chamber mounting assembly 410, internal heater 412, external heater 414, boiler 416, and rotational system 416 to communicate with one another and/or share resources. In various embodiments, the computing network can comprise a cloud network (IAN), a SAN (e.g., a small area network, a server area network, and/or a system area network), a wide area network (WAN), a local area network (LAN), a wireless local area network (WLAN), a metropolitan area network (MAN), an enterprise private network (EPN), a virtual private network (VPN), and/or a personal area network (PAN), among other examples of private and/or public computing networks and/or sets of devices that are possible and contemplated herein.

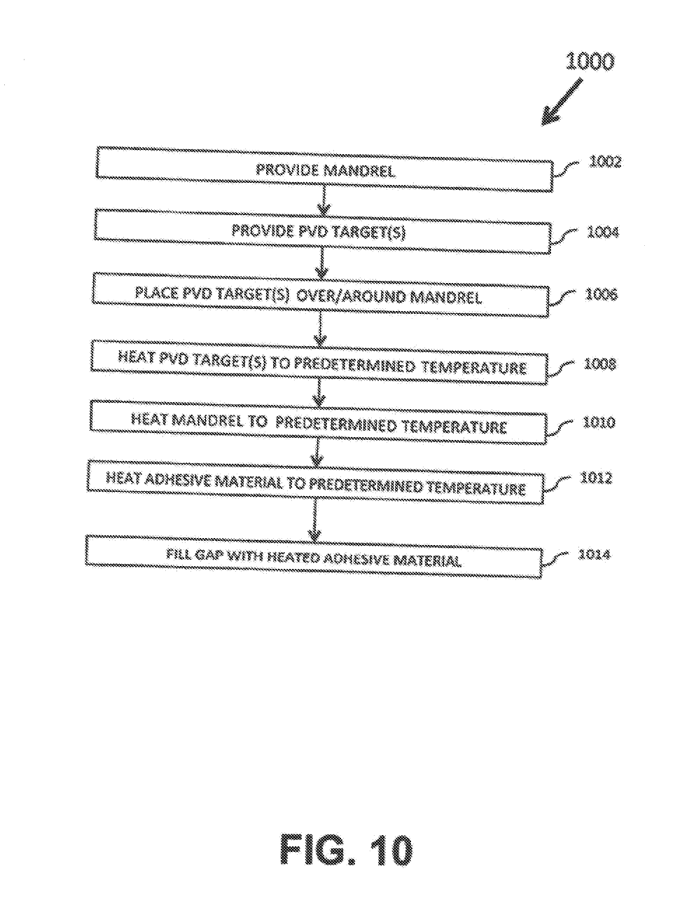

With reference to FIG. 10, FIG. 10 is a flow diagram of one embodiment of a method 1000 for creating a PVD mandrel-target assembly 300. At least in the illustrated embodiment, the method begins by an operator controller 900a/900b (also simply referred to individually, in various groups, or collectively, as operator controller(s) 900) instructing an articulator 402 to provide a mandrel 100 (block 1002) and provide one or more PVD targets 200 (block 1004). The mandrel 100 and PVD target(s) 200 made be provided in a pre-determined pattern or order, as discussed elsewhere herein. The operator controller 900 may instruct a robotic load/unload assembly 408 to place the PVD target(s) 200 around the mandrel 100 (block 1006) such that the mandrel 100 is within the PVD target(s) 200 to create a PVD mandrel-target assembly 300 including a gap 302 between an exterior surface 102 of the mandrel 100 and an interior surface 202 of the PVD target 200.

Further, the operator controller 900 may instruct an external heater 414 to heat the exterior surface 210 of the PVD target 200 to a predetermined temperature (block 1008), instruct an internal heater 412 to heat the interior surface 106 of a mandrel 100 to the predetermined temperature (block 1010), and instruct a boiler 416 to heat an adhesive material store in its reservoir 802 to the predetermined temperature (block 1012). The predetermined temperature may be any suitable temperature that allows the adhesive material to more easily fill the gap 302 as it is poured, injected, or otherwise introduced, as discussed elsewhere herein.

In addition, the operator controller 900 may further instruct the boiler 416 to fill the gap 302 with the heated adhesive material (block 1014). In some embodiments, the mandrel 100, PVD target(s) 200, and adhesive material may include the same temperature at the time the adhesive material is poured, injected, or otherwise introduced into the gap 302, as discussed elsewhere herein.

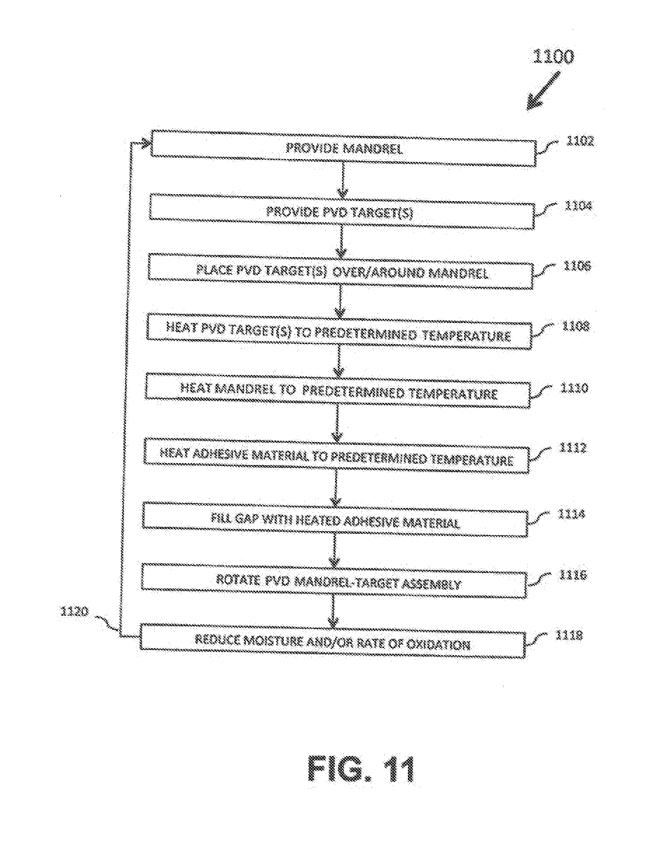

Referring now to FIG. 11, FIG. 11 is a flow diagram of another embodiment of a method 1100 for creating a PVD mandrel-target assembly 300. At least in the illustrated embodiment, the method begins by an operator controller 900 instructing an articulator 402 to provide a mandrel 100 (block 1102) and provide one or more PVD targets 200 (block 1104). The mandrel 100 and PVD target(s) 200 made be provided in a pre-determined pattern or order, as discussed elsewhere herein. The operator controller 900 may instruct a robotic load/unload assembly 408 to place the PVD target(s) 200 over/around the mandrel 100 (block 1106) such that the mandrel 100 is within the PVD target(s) 200 to create a PVD mandrel-target assembly 300 including a gap 302 between an exterior surface 102 of the mandrel 100 and an interior surface 202 of the PVD target 200.

Further, the operator controller 900 may instruct an external heater 414 to heat the exterior surface 210 of the PVD target 200 to a predetermined temperature (block 1108), instruct an internal heater 412 to heat the interior surface 106 of a mandrel 100 to the predetermined temperature (block 1110), and instruct a boiler 416 to heat an adhesive material store in its reservoir 802 to the predetermined temperature (block 1112). The predetermined temperature may be any suitable temperature that allows the adhesive material to more easily fill the gap 302 as it is poured, injected, or otherwise introduced, as discussed elsewhere herein.

In addition, the operator controller 900 may further instruct the boiler 416 to fill the gap 302 with the heated adhesive material (block 1114). In some embodiments, the mandrel 100, PVD target(s) 200, and adhesive material may include the same temperature at the time the adhesive material is poured, injected, or otherwise introduced into the gap 302, as discussed elsewhere herein.

The operator controller 900 may further instruct a rotational system 418 to rotate the PVD mandrel-target assembly 300 (block 1116). The PVD mandrel-target assembly 300 may be rotated at a constant speed when filling the gap 302 with the heated adhesive material to create an amount of centrifugal force that allows the gap 302 to be uniformly filled with the heated adhesive material, as discussed elsewhere herein.

Further, the operator controller 900 may instruct a shower system 406 or portion(s) 406a-406c thereof to reduce moisture and/or a rate of oxidation (block 1118). To reduce moisture and/or a rate of oxidation, a shower system 406 or portion(s) 406a-406c thereof may shower the mandrel 100 and the PVD target(s) 200 with nitrogen prior to the mandrel 100 being in the PVD target 200, shower a PVD mandrel-target assembly 300 with nitrogen before filling the gap 302 with the heated adhesive material, and/or shower a PVD mandrel-target assembly 300 with nitrogen after the exterior surface 102 of the mandrel 100 and the interior surface 202 of the PVD target 200 are coupled.

The operator controller 900 may perform one or more iterations of the operations in blocks 1102 through 1118 to create one or more PVD mandrel-target assemblies 300 (return 1120). The quantity of subsequent iterations can be any quantity and/or the operations of blocks 1102 through 1118 may be repeated for as many mandrels 100 and/or PVD targets 200 that may be provided in subsequent blocks 1102 and/or 1104.

In review, methods, systems, and apparatus for fabricating a PVD mandrel-target assembly are disclosed. One method includes providing a mandrel comprising a first exterior surface, a first interior surface defining a first hollow center portion of the mandrel, and a first pair of lateral dimensions, providing a PVD target comprising a second exterior surface, a second interior surface defining a second hollow center portion of the PVD target, and a second pair of lateral dimensions greater than the first pair of lateral dimensions, and placing the second hollow center portion of the PVD target around a first portion of the mandrel such that the first portion resides in the second hollow portion to create a PVD mandrel-target assembly including space between the first exterior surface of the mandrel and the second interior surface of the PVD target. The method further includes heating the second exterior surface of the PVD target to a predetermined temperature, heating the first interior surface of the mandrel to the predetermined temperature, heating an adhesive material to the predetermined temperature, and filling the space with the heated adhesive material to couple the first exterior surface of the mandrel and the second interior surface of the PVD target such that the heated adhesive material, the first exterior surface of the mandrel, and the second interior surface of the PVD target include the predetermined temperature while the space is being filled.

A method, in some embodiments, may further include rotating the PVD mandrel-target assembly at a constant speed when filling the space with the heated adhesive material to create an amount of centrifugal force that allows the space to be uniformly filled with the heated adhesive material. In additional of alternative embodiments, a method may include reducing moisture and a rate of oxidation by showering the mandrel and the PVD target with nitrogen prior to the first portion of the mandrel being housed in the hollow center portion of the PVD target, showering the PVD mandrel-target assembly with nitrogen before filling the space with the heated adhesive material, and/or showering the PVD mandrel-target assembly with nitrogen after the exterior surface of the mandrel and the first interior surface of the PVD target are coupled.

In various embodiments, a method can further include providing one or more additional PVD targets and placing a third hollow portion in each of the one or more additional PVD targets around one or more additional portions of the mandrel such that the one or more additional portions are housed in the third hollow portion in each of the one or more additional PVD targets to create one or more additional spaces. Here, the method may further include heating a third exterior surface in each of the one or more additional PVD targets to the predetermined temperature and filling the one or more additional spaces with the heated adhesive material to couple the first exterior surface of the mandrel and the third interior surface in each of the one or more additional PVD targets such that the heated adhesive material, the first exterior surface of the mandrel, and the third interior surface in each of the one or more additional PVD targets include the predetermined temperature when the one or more additional spaces are filled.

In some embodiments, the method further includes showering the mandrel and the one or more additional PVD targets with nitrogen prior to housing the mandrel in any PVD target, showering the PVD mandrel-target assembly with nitrogen before filling any space with the heated adhesive material, and/or showering the PVD mandrel-target assembly after filling the one or more additional spaces with the heated adhesive material. In additional or alternative embodiments, providing the mandrel, providing the PVD target, and providing the one or more additional PVD targets comprises providing the mandrel, the PVD target, and the one or more additional PVD targets in a predetermined pattern.

A system includes means for providing mandrels and PVD targets in which each mandrel comprises a first exterior surface, a first interior surface defining a first hollow center portion of the mandrel, and a first pair of lateral dimensions and each PVD target comprises a second exterior surface, a second interior surface defining a second hollow center portion of the PVD target, and a second pair of lateral dimensions greater than the first pair of lateral dimensions, and means for placing the second hollow center portion of a PVD target around a portion of a mandrel such that the portion of the mandrel resides in the second hollow center portion to create a PVD mandrel-target assembly including space between the first exterior surface of the mandrel and the second interior surface of the PVD target. The system further includes an internal heater removably in thermal communication with the first interior surface of the mandrel and configured to heat the first interior surface to a predetermined temperature, an external heater removably in thermal communication with the second exterior surface of the PVD target and configured to heat the second exterior surface to the predetermined temperature, and a boiler removably in fluid communication with the space, the boiler configured to heat an adhesive material to the predetermined temperature and fill the space with the heated adhesive material such that the boiler, the external heater, and the internal heater are cooperatively configured to heat the adhesive material, the first interior surface of the mandrel, and the second exterior surface of the PVD target to the predetermined temperature while the space is being filled.

In some embodiments, the means for placing the second hollow center portion of the PVD target around the portion of the mandrel comprises a robotic load/unload assembly including six degrees of freedom. In additional or alternative embodiments, the means for providing the mandrels and the PVD targets comprises an articulator to arrange the mandrels and the PVD targets in a predetermined pattern and a conveyor system coupled to the articulator and configured to provide the predetermined pattern of mandrels and PVD targets to the robotic load/unload assembly.

A system, in various embodiments, can further comprise a rotational system to rotate the PVD mandrel-target assembly at a constant speed while the space is being filled with the heated adhesive material to create an amount of centrifugal force that allows the space to be uniformly filled with the heated adhesive material. In additional or alternative embodiments, a system includes a shower system configured to reduce moisture and a rate of oxidation comprising a first portion at a first location and configured to shower the mandrel and the PVD target with nitrogen prior to the portion of the mandrel being housed in the second hollow center portion of the PVD target, a second portion at a second location and configured to shower the PVD mandrel-target assembly with nitrogen before filling the space with the heated adhesive material, and/or a third portion at a third location and configured to shower the PVD mandrel-target assembly with nitrogen after the first exterior surface of the mandrel and the second interior surface of the PVD target are coupled.

In some embodiments, the external heater comprises a first heater wrap and/or a heater cage for removably covering the PVD target to heat the second exterior surface of the PVD target. In additional or alternative embodiments, the boiler includes a reservoir to store the adhesive material, a second heater wrap covering the reservoir and configured to heat the adhesive material, and means for delivering the heated adhesive material to fill the space.

One apparatus includes a source module that operates an articulator and conveyor system that provides a predetermined pattern of mandrels and PVD targets to a robotic load/unload assembly in which each mandrel comprises a first exterior surface, a first interior surface defining a first hollow center portion of the mandrel, and a first pair of lateral dimensions and each PVD target comprises a second exterior surface, a second interior surface defining a second hollow center portion of the PVD target, and a second pair of lateral dimensions greater than the first pair of lateral dimensions, and an assembly module that operates the robotic load/unload assembly to place a second hollow center portion of a PVD target around a portion of a mandrel such that the portion of the mandrel resides in the second hollow center portion to create a PVD mandrel-target assembly including space between the first exterior surface of the mandrel and the second interior surface of the PVD target. The apparatus further includes an internal heater module that operates an internal heater removably in thermal communication with the first interior surface of the mandrel and configured to heat the first interior surface to a predetermined temperature, an external heater module that operates an external heater removably in thermal communication with the second exterior surface of the PVD target and configured to heat the second exterior surface to the predetermined temperature, and a boiler module that operates a boiler removably in fluid communication with the space and configured to heat an adhesive material to the predetermined temperature and fill the space with the heated adhesive material such that the boiler module, the external heater module, and the internal heater module are cooperatively configured to heat the adhesive material, the first interior surface of the mandrel, and the second exterior surface of the PVD target to the predetermined temperature while the space is being filled.

Some apparatus further include a rotation module that operates a rotational system to rotate the PVD mandrel-target assembly at a constant speed while the space is being filled with the heated adhesive material to create an amount of centrifugal force that allows the space to be uniformly filled with the heated adhesive material. In additional or alternative embodiments, an apparatus may further include a shower module that operates a shower system configured to reduce moisture and a rate of oxidation in which the shower module operates a first portion at a first location and configured to shower the mandrel and the PVD target with nitrogen prior to the portion of the mandrel being housed in the second hollow center portion of the PVD target, a second portion at a second location and configured to shower the PVD mandrel-target assembly with nitrogen before filling the space with the heated adhesive material, and/or a third portion at a third location and configured to shower the PVD mandrel-target assembly with nitrogen after the first exterior surface of the mandrel and the second interior surface of the PVD target are coupled.

The various embodiments may be practiced in other specific forms. The described embodiments are to be considered in all respects only as illustrative and not restrictive. The scope of the technology is, therefore, indicated by the appended claims rather than by the foregoing description. All changes that come within the meaning and range of equivalency of the claims are to be embraced within their scope.

1. A method, comprising:
providing a mandrel comprising a first exterior surface, a first interior surface defining a first hollow center portion of the mandrel, and a first pair of lateral dimensions;
providing a physical vapor deposition (PVD) target comprising a second exterior surface, a second interior surface defining a second hollow center portion of the PVD target, and a second pair of lateral dimensions greater than the first pair of lateral dimensions;
placing the second hollow center portion of the PVD target around a first portion of the mandrel such that the first portion resides in the second hollow portion to create a PVD mandrel-target assembly including space between the first exterior surface of the mandrel and the second interior surface of the PVD target;
heating the second exterior surface of the PVD target to a predetermined temperature;
heating the first interior surface of the mandrel to the predetermined temperature;
heating an adhesive material to the predetermined temperature; and
filling the space with the heated adhesive material to couple the first exterior surface of the mandrel and the second interior surface of the PVD target,
wherein the heated adhesive material, the first exterior surface of the mandrel, and the second interior surface of the PVD target include the predetermined temperature while the space is being filled.

2. The method of claim 1, method further comprising:
rotating the PVD mandrel-target assembly at a constant speed when filling the space with the heated adhesive material to create an amount of centrifugal force that allows the space to be uniformly filled with the heated adhesive material.

3. The method of claim 1, further comprising:
reducing moisture and a rate of oxidation by one of:
showering the mandrel and the PVD target with nitrogen prior to the first portion of the mandrel being housed in the hollow center portion of the PVD target,
showering the PVD mandrel-target assembly with nitrogen before filling the space with the heated adhesive material, and
showering the PVD mandrel-target assembly with nitrogen after the exterior surface of the mandrel and the first interior surface of the PVD target are coupled.

4. The method of claim 1, further comprising:
reducing moisture and a rate of oxidation by two of:
showering the mandrel and the PVD target with nitrogen prior to the first portion of the mandrel being housed in the hollow center portion of the PVD target,
showering the PVD mandrel-target assembly with nitrogen before filling the space with the heated adhesive material, and
showering the PVD mandrel-target assembly with nitrogen after the exterior surface of the mandrel and the first interior surface of the PVD target are coupled.

5. The method of claim 1, further comprising:
reducing moisture and a rate of oxidation by:
showering the mandrel and the PVD target with nitrogen prior to the first portion of the mandrel being housed in the hollow center portion of the PVD target,
showering the PVD mandrel-target assembly with nitrogen before filling the space with the heated adhesive material, and
showering the PVD mandrel-target assembly with nitrogen after the exterior surface of the mandrel and the first interior surface of the PVD target are coupled.

6. The method of claim 1, further comprising:
providing one or more additional PVD targets;
placing a third hollow portion in each of the one or more additional PVD targets around one or more additional portions of the mandrel such that the one or more additional portions are housed in the third hollow portion in each of the one or more additional PVD targets to create one or more additional spaces;
heating a third exterior surface in each of the one or more additional PVD targets to the predetermined temperature; and
filling the one or more additional spaces with the heated adhesive material to couple the first exterior surface of the mandrel and the third interior surface in each of the one or more additional PVD targets,
wherein the heated adhesive material, the first exterior surface of the mandrel, and the third interior surface in each of the one or more additional PVD targets include the predetermined temperature when the one or more additional spaces are filled.

7. The method of claim 6, further comprising one of:
showering the mandrel and the one or more additional PVD targets with nitrogen prior to housing the mandrel in any PVD target;
showering the PVD mandrel-target assembly with nitrogen before filling any space with the heated adhesive material; and
showering the PVD mandrel-target assembly after filling the one or more additional spaces with the heated adhesive material.

8. The method of claim 6, wherein providing the mandrel, providing the PVD target, and providing the one or more additional PVD targets comprises providing the mandrel, the PVD target, and the one or more additional PVD targets in a predetermined pattern.

9. A system, comprising:
means for providing mandrels and physical vapor deposition (PVD) targets, wherein:
each mandrel comprises a first exterior surface, a first interior surface defining a first hollow center portion of the mandrel, and a first pair of lateral dimensions, and
each PVD target comprises a second exterior surface, a second interior surface defining a second hollow center portion of the PVD target, and a second pair of lateral dimensions greater than the first pair of lateral dimensions;
means for placing the second hollow center portion of a PVD target around a portion of a mandrel such that the portion of the mandrel resides in the second hollow center portion to create a PVD mandrel-target assembly including space between the first exterior surface of the mandrel and the second interior surface of the PVD target;
an internal heater removably in thermal communication with the first interior surface of the mandrel and configured to heat the first interior surface to a predetermined temperature;
an external heater removably in thermal communication with the second exterior surface of the PVD target and configured to heat the second exterior surface to the predetermined temperature; and
a boiler removably in fluid communication with the space, the boiler configured to heat an adhesive material to the predetermined temperature and fill the space with the heated adhesive material,
wherein the boiler, the external heater, and the internal heater are cooperatively configured to heat the adhesive material, the first interior surface of the mandrel, and the second exterior surface of the PVD target to the predetermined temperature while the space is being filled.

10. The system of claim 9, wherein the means for placing the second hollow center portion of the PVD target around the portion of the mandrel comprises a robotic load/unload assembly including six degrees of freedom.

11. The system of claim 10, wherein the means for providing the mandrels and the PVD targets comprises:
an articulator to arrange the mandrels and the PVD targets in a predetermined pattern; and
a conveyor system coupled to the articulator and configured to provide the predetermined pattern of mandrels and PVD targets to the robotic load/unload assembly.

12. The system of claim 9, further comprising:
a rotational system to rotate the PVD mandrel-target assembly at a constant speed while the space is being filled with the heated adhesive material to create an amount of centrifugal force that allows the space to be uniformly filled with the heated adhesive material.

13. The system of claim 9, further comprising:
a shower system configured to reduce moisture and a rate of oxidation, the shower system comprising one of:
a first portion at a first location and configured to shower the mandrel and the PVD target with nitrogen prior to the portion of the mandrel being housed in the second hollow center portion of the PVD target,
a second portion at a second location and configured to shower the PVD mandrel-target assembly with nitrogen before filling the space with the heated adhesive material, and
a third portion at a third location and configured to shower the PVD mandrel-target assembly with nitrogen after the first exterior surface of the mandrel and the second interior surface of the PVD target are coupled.

14. The system of claim 9, further comprising:
a shower system configured to reduce moisture and a rate of oxidation, the shower system comprising two of:
a first portion at a first location and configured to shower the mandrel and the PVD target with nitrogen prior to the portion of the mandrel being housed in the second hollow center portion of the PVD target,
a second portion at a second location and configured to shower the PVD mandrel-target assembly with nitrogen before filling the space with the heated adhesive material, and
a third portion at a third location and configured to shower the PVD mandrel-target assembly with nitrogen after the first exterior surface of the mandrel and the second interior surface of the PVD target are coupled.

15. The system of claim 9, further comprising:
a shower system configured to reduce moisture and a rate of oxidation, the shower system comprising:
a first portion at a first location and configured to shower the mandrel and the PVD target with nitrogen prior to the portion of the mandrel being housed in the second hollow center portion of the PVD target,
a second portion at a second location and configured to shower the PVD mandrel-target assembly with nitrogen before filling the space with the heated adhesive material, and
a third portion at a third location and configured to shower the PVD mandrel-target assembly with nitrogen after the first exterior surface of the mandrel and the second interior surface of the PVD target are coupled.

16. The system of claim 9, wherein:
the external heater comprises one of a first heater wrap and a heater cage for removably covering the PVD target to heat the second exterior surface of the PVD target; and
the boiler comprises:
a reservoir to store the adhesive material,
a second heater wrap covering the reservoir and configured to heat the adhesive material, and
means for delivering the heated adhesive material to fill the space.

17. An apparatus, comprising:
a source module that operates an articulator and conveyor system that provides a predetermined pattern of mandrels and physical vapor deposition (PVD) targets to a robotic load/unload assembly, wherein:
each mandrel comprises a first exterior surface, a first interior surface defining a first hollow center portion of the mandrel, and a first pair of lateral dimensions, and
each PVD target comprises a second exterior surface, a second interior surface defining a second hollow center portion of the PVD target, and a second pair of lateral dimensions greater than the first pair of lateral dimensions;
an assembly module that operates the robotic load/unload assembly to place a second hollow center portion of a PVD target around a portion of a mandrel such that the portion of the mandrel resides in the second hollow center portion to create a PVD mandrel-target assembly including space between the first exterior surface of the mandrel and the second interior surface of the PVD target;
an internal heater module that operates an internal heater removably in thermal communication with the first interior surface of the mandrel and configured to heat the first interior surface to a predetermined temperature;
an external heater module that operates an external heater removably in thermal communication with the second exterior surface of the PVD target and configured to heat the second exterior surface to the predetermined temperature; and
a boiler module that operates a boiler removably in fluid communication with the space and configured to heat an adhesive material to the predetermined temperature and fill the space with the heated adhesive material,
wherein the boiler module, the external heater module, and the internal heater module are cooperatively configured to heat the adhesive material, the first interior surface of the mandrel, and the second exterior surface of the PVD target to the predetermined temperature while the space is being filled.

18. The apparatus of claim 17, further comprising:
a rotation module that operates a rotational system to rotate the PVD mandrel-target assembly at a constant speed while the space is being filled with the heated adhesive material to create an amount of centrifugal force that allows the space to be uniformly filled with the heated adhesive material.

19. The apparatus of claim 17, further comprising:
a shower module that operates a shower system configured to reduce moisture and a rate of oxidation, the shower module operating one of:
a first portion at a first location and configured to shower the mandrel and the PVD target with nitrogen prior to the portion of the mandrel being housed in the second hollow center portion of the PVD target,
a second portion at a second location and configured to shower the PVD mandrel-target assembly with nitrogen before filling the space with the heated adhesive material, and
a third portion at a third location and configured to shower the PVD mandrel-target assembly with nitrogen after the first exterior surface of the mandrel and the second interior surface of the PVD target are coupled.

20. The apparatus of claim 17, further comprising:
a shower module that operates a shower system configured to reduce moisture and a rate of oxidation, the shower module operating:
a first portion at a first location and configured to shower the mandrel and the PVD target with nitrogen prior to the portion of the mandrel being housed in the second hollow center portion of the PVD target,
a second portion at a second location and configured to shower the PVD mandrel-target assembly with nitrogen before filling the space with the heated adhesive material, and
a third portion at a third location and configured to shower the PVD mandrel-target assembly with nitrogen after the first exterior surface of the mandrel and the second interior surface of the PVD target are coupled.
